(19) United States
(12) Patent Application Publication
(10) Pub. No.: US 2026/0206356 A1
(43) Pub. Date: Jul. 16, 2026

(54) TWO-STAGE MANUFACTURING FOR ELECTRO-ABSORPTION MODULATOR AND PHOTODIODE

(71) Applicant: Celestial AI, Inc., Santa Clara, CA (US)

(72) Inventor: Subal SAHNI, La Jolla, CA (US)

(21) Appl. No.: 19/020,447

(22) Filed: Jan. 14, 2025

(51) Int. Cl. H10F 71/00; H10F 39/95

(52) U.S. Cl. CPC H10F 71/1215; H10F 39/95

(57) ABSTRACT

A two-stage manufacturing process is disclosed for photodiodes (PDs), electro-absorption modulators (EAMs), and waveguides, disposed on a common silicon substrate (i.e., a single chip), for use in chip-scale packaged photonic integrated circuits (PICs) providing photonic interfaces, for example, for multi-dimensional electro-photonic memory fabrics having high interconnect bandwidth requirements. Different processing steps are separately utilized during non-synchronous sequential manufacturing stages on the chip to thereby optimize the epitaxial growth conditions for the individual PD and EAM devices which have different unique design requirements, structures, and functions. The two-stage processes provide epitaxial structures having better performance with fewer defects compared to those produced by conventional single-stage processes.

### BACKGROUND

Single stage epitaxy refers to a method of growing a crystalline layer on a substrate in a single step, where the orientation and properties of the layer are determined by the underlying crystal structure. This process is particularly significant in the semiconductor industry for the fabrication of high-quality materials used in semiconductor devices. EICs (electronic integrated circuits) and PICs (photonic integrated circuits) are two types of semiconductors having components manufactured using epitaxy that play crucial roles in modern technology, particularly in the fields of electronics and photonics.

### SUMMARY

Conventional single-stage epitaxy processes are not optimized for the manufacturing of PICs utilized as photonic interface components used in photonic fabrics such as those used to connect computing and memory infrastructure in artificial intelligence (AI) computing where high bandwidth density is required. Photonic interfaces comprise active semiconductor components including photodiodes (PDs), electro-absorption modules (EAMs), and waveguides supporting optical signal paths, which are fabricated on a common silicon substrate (i.e., a single chip). The PDs and EAMs are fabricated using epitaxy processes as monolithic devices on chip-scale packaged PICs. However, current single-stage processes can significantly constrain freedom of design and application of the fabricated epitaxial structures. For example, material selection, surface characteristics, growth conditions, scalability, and interface integrity, among other parameters, are limited to what the single-stage processing will support. Requiring epitaxial structures to be fabricated in the same way at the same time is less than optimal for photonic interfaces because the constituent PDs and EAMs have different structures with different functions.

The disclosed two-stage manufacturing enables epitaxial fabrication to be independently optimized and tailored to the unique design requirements of the different semiconductor components in the photonic interface PICs. Separate and distinct processing steps are utilized during non-time-synchronous sequential manufacturing stages for the individual PD and EAM epitaxial structures on a single chip. The two-stage manufacturing provides for greater design flexibility by allowing for uniquely optimized high-quality epitaxial growth of the layers for the separate PD and EAM structures. Providing ideal growth conditions (e.g., pressure, temperature, growth rate, gas composition, gas flow rate, etc.) for each of the separate PD and EAM fabrication stages results in improved material quality with fewer dislocations, stacking faults, irregular nucleation, and other defects that can degrade photonic interface integrity and performance. Optimized processing for the PD and EAM epitaxial structures improves manufacturing yields to lower the per-part costs of the PICs.

In a first illustrative embodiment of the present two-stage manufacturing, chemical mechanical planarization (CMP) is utilized over the PIC wafer after an epitaxial growth for one of the active components (i.e., the PD or EAM) in the first stage of the two-stage manufacturing. The CMP processing step provides a suitable foundation for deposition of a protection layer over the wafer. The protection layer protects the previously grown component in the first stage to thereby enable subsequential selective epitaxy for the other active component to be grown in the second stage. A second CMP processing step is then utilized to provide the PD and EAM with substantially the same overall thickness.

In a second illustrative embodiment of the present two-stage manufacturing, CMP is not utilized at all—neither between the first and second stages of epitaxial growth, nor after growth of the epitaxial structure in the second stage. Instead, selective area epitaxy growth is utilized to enable precise control over epitaxial film locations and thicknesses by using epitaxy inhibition layers and tuning the appropriate growth parameters.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Furthermore, the claimed subject matter is not limited to implementations that solve any or all disadvantages noted in any part of this disclosure.

### DESCRIPTION OF THE DRAWINGS

FIG. 1 is a block diagram of an illustrative memory fabric for connecting circuit packages that include PICs fabricated in accordance with the present principles;

FIGS. 2 and 3 are side views of circuit packages that include PICs fabricated in accordance with the present principles;

FIGS. 4-10, 12, and 13 show sequential steps in a first illustrative embodiment of a two-stage manufacturing process for a PD and an EAM that are epitaxially grown on a unitary silicon chip in accordance with the present principles, in which chemical mechanical planarization (CMP) is utilized;

FIG. 11 shows an illustrative taxonomy 1100 of exemplary epitaxial growth conditions;

FIGS. 14A, 14B, and 15 are flowcharts of illustrative methods for embodiments of two-stage manufacturing of epitaxial structures in accordance with the present principles in which CMP is utilized;

FIGS. 16-24 show sequential steps in a second illustrative embodiment of a two-stage manufacturing process for a PD and an EAM that are epitaxially grown on a unitary silicon chip in accordance with the present principles, in which CMP is not utilized;

FIGS. 25A, 25B, and 26 are flowcharts of illustrative methods for embodiments of two-stage manufacturing of epitaxial structures in accordance with the present principles in which CMP is not utilized;

FIG. 27 is a block diagram of illustrative components utilized in a memory fabric arranged for connecting circuit packages that include PICs fabricated in accordance with the present principles;

FIG. 28 is a top view of an illustrative arrangement for a memory fabric for connecting circuit packages that include PICs fabricated in accordance with the present principles; and

FIG. 29 is a top view of an illustrative arrangement for a three-dimensional memory fabric for connecting circuit packages that include PICs fabricated in accordance with the present principles.

Like reference numerals indicate like elements in the drawings. Elements are not drawn to scale in the drawings.

### DETAILED DESCRIPTION

Applications like machine learning (ML), deep learning (DL), natural language processing (NLP), and machine vision (MV) are becoming more complex over time and are being developed to handle more sophisticated tasks. Computing devices, however, have not advanced at a pace where they can effectively handle the needs of these new applications. Without sufficiently advanced computing paradigms, ML, DL, NLP, and MV applications, for example, cannot reach their full potential.

One solution is to connect many chips into a system where the chips can send data between each other with low latency and at high speed. In one approach, connections between chips are made using Serializer/Deserializer (SerDes) blocks that convert parallel messages into serial bit streams that can be sent over electrical interconnects or optical fibers between chips. In such systems, a distinction is made between on-chip and off-chip communication. For example, compute elements on the chip use a metal interconnection while messages destined for another chip must move over the chip level interconnects to the site of the interface to the SerDes where the data is converted to a bit stream and is transmitted optically. In the receive direction, bits arrive on an optical fiber or electrical interconnect, are assembled, and are then transmitted over metal interconnects inside the chip to the destination processor or memory. Significant energy is expended both in moving the data within the chip to the SerDes and then from the SerDes into other chips in the system.

Additionally, the performance of a system when processing a workload is limited by memory and interconnect bandwidth. Data movement, which leads to massive power consumption, poor performance, and excessive latency, exacerbates this problem, particularly with the exponential increase of AI workloads. Conventional digital computing environments that rely on electrical interconnects are inadequate for the required data movement of AI workloads. Accordingly, some existing systems use hybrid electro-photonic computing. However, these existing systems suffer from inefficiencies due to moving data across large distances and poor management of the thermal environment.

The present application discloses a method for epitaxial manufacturing of optical components including electro-absorption modules (EAMs) and photodiodes (PDs) that are utilizable as a part of a circuit package that includes a PIC. In an illustrative use environment, the circuit package is connected to an N-dimensional electro-photonic memory fabric adapted to receive message packets from a client compute element such as a microprocessor unit (MPU), central processing unit (CPU), graphics processing unit (GPU), artificial intelligence (AI) accelerator, or another digital application-specific integrated circuit (ASIC), or from a memory element.

When moving data within a chip and between chips, the electro-photonic memory fabric enables low-latency and low-power data movement. For example, the fabric is formed out of nodes that are connected by optical links, both within a chip and between chips. Data is moved from a source node to a destination node in the fabric by moving the data between the source node and any intermediate nodes until it reaches the destination node. At each node, message routers move the data along the next hop in the path. For example, when a node receives data along an optical link, the message routers perform optical-to-electrical conversion and electrical-to-optical conversion to transfer the data to the next node along the optical link. At the destination node, the signal is transformed into an electrical form and used by a processor and/or memory associated with the destination node.

The electro-photonic memory fabric provides a hybrid electro-photonic computing environment for moving data or instructions photonically by sending a packet of data as an electromagnetic wave in an optical carrier, such as a waveguide or fiber. By sending data or instructions optically, the system is fast and consumes minimal power. Additionally, the electro-photonic memory fabric achieves an efficient balance of transmitting, receiving, converting, processing, and modifying data in both the optical and electrical domains.

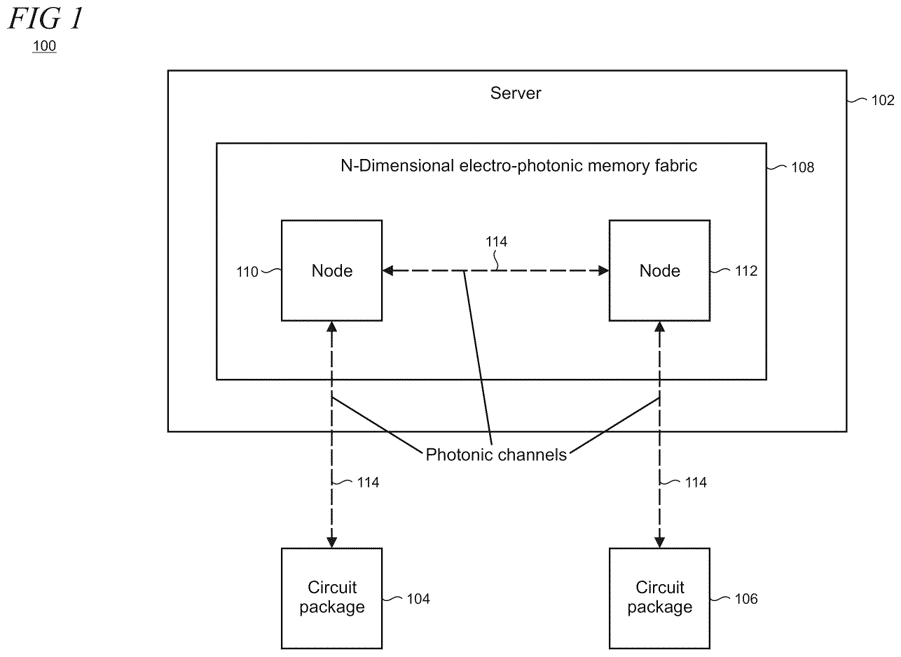

Turning now to the drawings, FIG. 1 shows a block diagram of an example memory fabric for connecting one or more circuit packages according to one or more embodiments described in this disclosure. To illustrate, FIG. 1 includes a system 100 having a server 102 and circuit packages (i.e., the circuit package 104 and circuit package 106). As shown, the system 100 includes a memory fabric (shown as an N-dimensional electro-photonic memory fabric 108) with two nodes (i.e., node 110 and node 112). While FIG. 1 shows a particular number of nodes and circuit packages, the system 100 can include any number of nodes and circuit packages.

The components in FIG. 1 show various interconnections. To illustrate, the interconnections shown in FIG. 1 include photonic channels 114. Although not explicitly shown in FIG. 1, the memory fabric and the circuit packages commonly include an electronic integrated circuit (EIC) and/or a photonic integrated circuit (PIC), such that each of the nodes and each of the circuit packages has at least one photonic transceiver whose functionality resides partially in the EIC and/or partially in the PIC. This enables the photonic transceivers to send and receive data packets in the optical domain as modulated electromagnetic waves via the photonic channels 114 or as digital packets via electrical interconnections.

The photonic transceiver includes, for example, active or passive components in the EIC and active or passive components in the PIC directly bonded together or stacked on top of each other, in a chip-to-chip configuration. For example, a copper pillar or another electrical connection connects the active components in the EIC to the active components in the PIC. In this way, the copper pillar bridges the gap, typically in the range of tens of microns. In these embodiments, the copper pillar bridges are essentially perpendicular to the plane of the EIC and the PIC, providing a chip-to-chip direct bonding of the layers. Further, this direct bonding, direct coupling, or stacking of the electrical interconnects between the electrical and the optical components maximizes the bandwidth of the photonic transceivers.

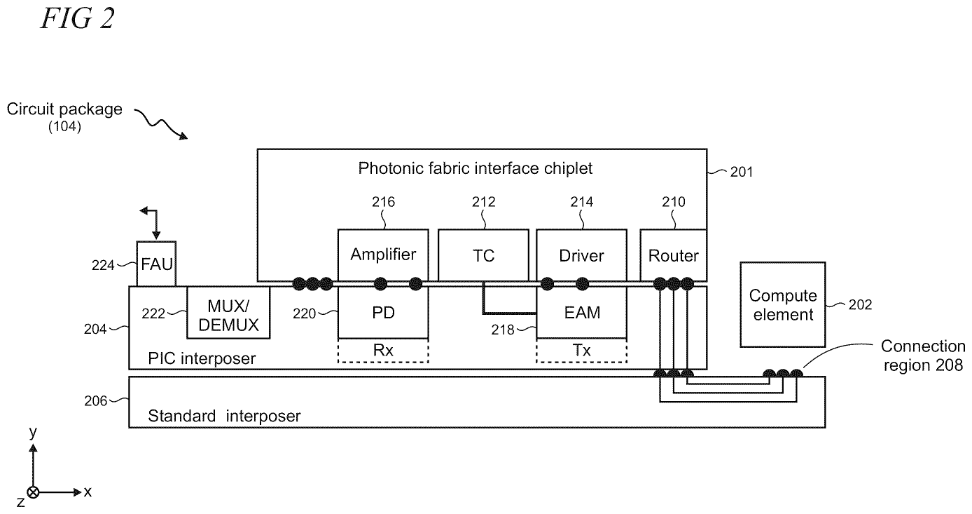

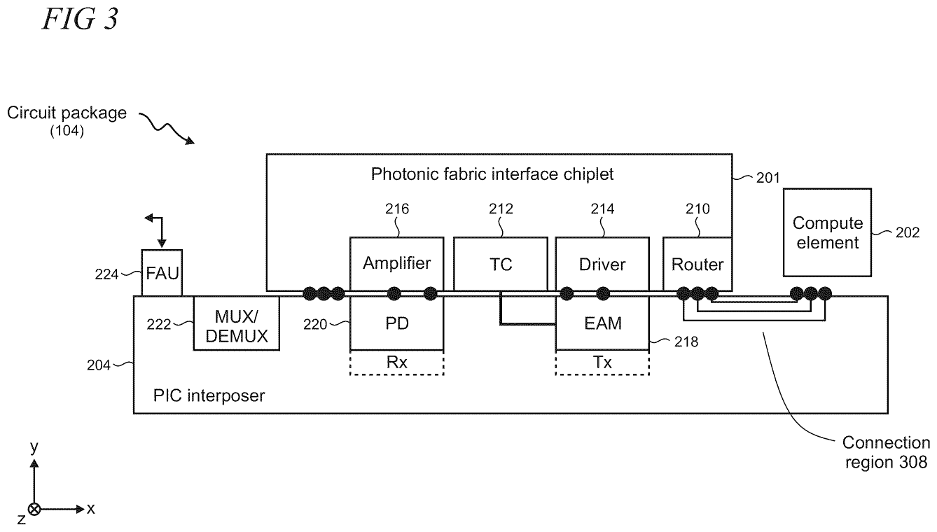

FIGS. 2 and 3 show different illustrative embodiments of a circuit package (for photonically connecting compute elements via a photonic interface). As shown in FIGS. 2 and 3, each circuit package includes a photonic fabric interface chiplet 201 arranged as an EIC, a compute element 202, and a PIC 204 that provides an interposer functionality. FIG. 2 also includes a standard interposer 206 (absent in FIG. 3), which is further described below. The compute element 202 may represent an MPU, GPU, CPU, AI accelerator, or another digital ASIC. The compute element may additionally or alternatively represent a memory element or device.

Additionally, the photonic fabric interface chiplet 201 in FIGS. 2 and 3 includes a router 210 for forming digital packets that include message requests from compute elements, a thermal control block 212, a driver 214, and an amplifier 216. The PIC interposer 204 includes an electro-absorption modulator (EAM) 218 for transmitting (Tx), a photo (PD) 220 for receiving (Rx), and a multiplexer/demultiplexer (MUX/DEMUX) 222 that is connected to a fiber array unit (FAU) 224 connected to the PIC interposer. As also shown, the EAM and the PD disposed in the PIC interposer connect to the driver and the amplifier of the photonic fabric interface chiplet, respectively. The PD and EAM each include respective input and output ports.

As noted above, FIG. 2 shows an arrangement with a standard interposer 206. More particularly, the circuit package 104 shows the compute element 202 connected to the photonic fabric interface chiplet 201 via a connection region 208 of the standard interposer. The standard interposer routes connections from the compute element 202 to the router 210 of the photonic fabric interface chiplet via the PIC interposer 204, as shown. In various embodiments, the thermal control block 212 sends signals to the EAM 218 in the PIC interposer 204 as appropriate. For example, the thermal control block provides a voltage input to the EAM when needed to extend its operating range depending on the current thermal conditions under which it is operating.

FIG. 3 shows an illustrative alternative arrangement that does not include a standard interposer. Rather, as shown, the circuit package 104 includes the PIC interposer 204 interfacing between the compute element 202 and the photonic fabric interface chiplet 201. For example, the PIC interposer 204 includes a connection region 209 that receives messages from the compute element 202 and provides electrical connections to the router 210 of the photonic fabric interface chiplet. The bottom surface of the photonic fabric interface chiplet electronically connects to the connection region 308 of the PIC interposer 204.

In various illustrative embodiments, the router 210 shown in FIGS. 2 and 3 comprises a message router that resides partially in the PIC interposer 204 and partially in the photonic fabric interface chiplet 201. In these embodiments, the router 210 is configured to convert an optical signal into digital packets in a receive unit and/or to convert digital packets into an optical signal in a transmit unit.

By coupling to the compute element 202, the photonic fabric interface chiplet 201 is capable of being connected photonically (e.g., via inter-chip or intra-chip links) to another photonic interface in another device. For example, the photonic fabric interface chiplet photonically connects the compute element to a server and/or a memory fabric. Also, while FIGS. 2 and 3 show the fiber array unit 224, the photonic fabric interface chiplet may bi-directionally connect photonically to other devices via a waveguide or other optical means. The FAU facilitates bi-directional communications with connected nodes and devices (e.g., transmitted and received laser light and/or messages occur for the PD via the FAU).

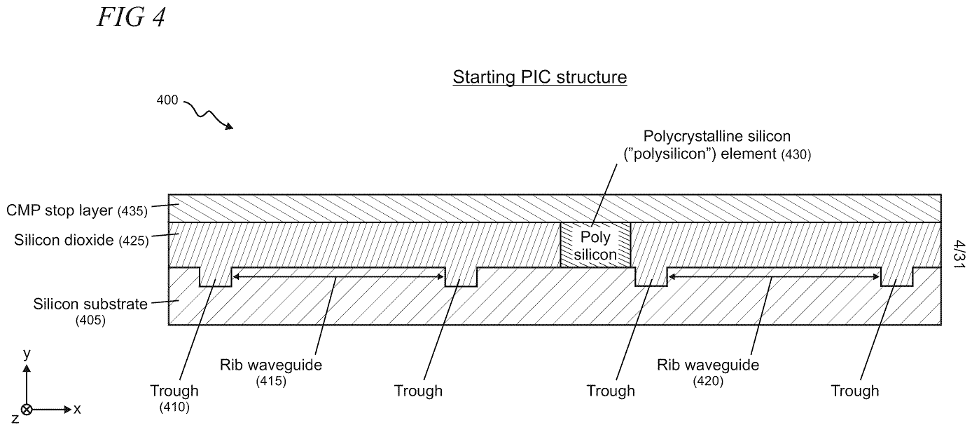

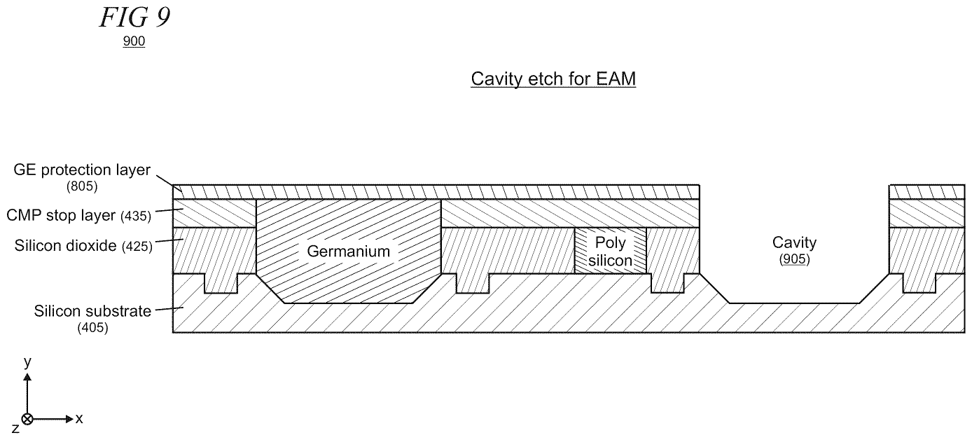

FIGS. 4-10, 12, and 13 show illustrative sequential steps in a first illustrative embodiment of a two-stage manufacturing process for a PD and an EAM that are epitaxially grown on a unitary silicon chip in accordance with the present principles. As used herein, the term “two-stage manufacturing” refers to epitaxial fabrication processes for each of the EAM and PD, fabricated on a common chip, that are performed separately in a non-time-synchronous sequential manner—one stage of the two-stage manufacturing including steps for fabricating one of the EAM or PD epitaxial structures and the other stage including steps for fabricating the other epitaxial structure. As illustratively shown in FIGS. 4-8, the first stage of the two-stage manufacturing is directed to fabrication of an epitaxial structure for the PD 220. The second stage of the two-stage manufacturing is directed to fabrication of an epitaxial structure for the EAM 218, as illustratively shown in FIGS. 9, 10, 12, and 13. In alternative embodiments, the first stage is utilized for EAM fabrication on the chip and the second stage is utilized for PD fabrication. Each stage comprises a number of discrete steps in which each step may include one or more constituent actions, controls, or processes.

Each stage of the two-stage manufacturing provides for optimization of processes for producing their respective PD and EAM devices. Typically, CMOS-type (complementary metal-oxide-semiconductor) silicon epitaxy processes are utilized in the present two-stage manufacturing to create high-quality crystalline layers with precise control over layer thickness, composition, and doping profiles with low-defect surfaces. However, as discussed below, new techniques and beneficial modifications to existing techniques are provided to enable differentially-implemented fabrication steps for the different devices which comprise different materials and perform different functions. Such process optimization enables functional optimization of the EAM and PD devices to improve performance and reliability. In addition, as defects can be reduced by using optimized processing, manufacturing yields are typically improved, which lowers per-chip costs.

FIG. 4 shows a first illustrative embodiment of a PIC structure 400 comprising a silicon substrate 405 that is provided as a starting point for the two-stage manufacturing. The starting PIC structure is usable as a component in the PIC 204, shown in FIG. 2 and described above, after various manufacturing processes are completed. It is noted that the description that follows is limited to the novel two-stage epitaxial growth of EAMs and PDs and does not include a discussion of the manufacturing and integration of other structures and components that are required for operation of the PIC 204 in its intended manner. It may be appreciated that these other components may be realized and implemented using conventional processes.

Typically, the silicon substrate 405 is implemented as a wafer that is subsequently processed using the epitaxial processing steps described herein, and other appropriate processes. Portions of the silicon substrate may be selectively doped, as appropriate with suitable materials, to support fabrication and realization of various contacts, busses, and other functional elements in the PIC. In-situ doping may also be utilized during subsequent epitaxial growth steps.

The silicon substrate includes a plurality of troughs (representatively indicated by reference numeral 410) that are typically formed using photolithography and etching processes. The troughs create rib waveguides 415 and 420 to be formed in the silicon substrate. During operation of the completed PIC in the circuit package 104 (FIG. 1), guided signal light propagates in the z-direction.

The starting PIC structure 400 further includes a silicon dioxide layer 425 providing a dielectric function that is typically deposited on the silicon substrate 405 using manufacturing techniques such as thermal oxidation or chemical vapor deposition (CVD). The silicon dioxide layer has a refractive index that differs from that of the silicon substrate to thus function as cladding for the rib waveguides 415 and 420.

An exemplary polycrystalline silicon (“polysilicon”) element 430 is disposed on the silicon substrate 405. While a single element is illustratively shown in FIG. 4, it may be appreciated that multiple polysilicon elements may be located in the starting structure for the PIC in various embodiments. For example, a layer of polysilicon may be initially deposited on the substrate and subsequently subjected to the application of suitable etching processes during the various stages of PIC fabrication to obtain a final desired structural configuration for the element. Advantageously, the present two-stage manufacturing techniques are compatible with any polysilicon element utilized in the PIC. The polysilicon remains protected during downstream manufacturing processes.

Such polysilicon element(s) may be utilized in the completed PIC (e.g., PIC 204 in FIG. 2), for example, for enhanced optical coupling between the silicon waveguide and the germanium absorption region of the PD. As the refractive index of the polysilicon has an intermediate value between that of silicon and germanium, it can help reduce mode mismatch and associated coupling losses. In an illustrative embodiment, the polysilicon element is configured to abut the input and output ports of one or more of the EAM or PD.

A CMP (chemical mechanical polishing, also commonly referred to as chemical mechanical planarization) stop layer 435 is also included in the starting PIC structure 400. The CMP stop layer is a sacrificial layer used in semiconductor fabrication to control polishing processes and protect underlying structures from over-polishing. The CMP stop layer can also mitigate erosion of other structures in the PIC during fabrication and facilitate effective material removal for achieving planar surfaces. The CMP stop layer is implemented, in this illustrative embodiment, with silicon dioxide which is deposited on the starting PIC structure using, for example, CVD. The silicon dioxide in the CMP stop layer further serves as a mask for selective epitaxial growth. Epitaxial material grows only in the exposed silicon areas, while the mask prevents growth on covered regions.

In typical conventional single-stage manufacturing of PDs and EAMs, the CMP stop layer thickness for silicon dioxide is commonly in a range of 100-200 nm. In some embodiments in which tighter tolerances are utilized to reduce total stack thickness of the starting PIC structure, a thinner CMP stop layer in the range of 50-100 nm may be utilized. It is noted that the effectiveness of the CMP stop layer depends not just on its thickness, but also on its material properties and the particular CMP chemistry used. In an illustrative, non-limiting, example for the present two-stage manufacturing, the CMP stop layer is increased in thickness, for example, by 50 nm, over that used in conventional single-stage manufacturing. The additional CMP stop layer thickness is utilized to provide additional protection for the germanium epitaxial structure during subsequent downstream processes.

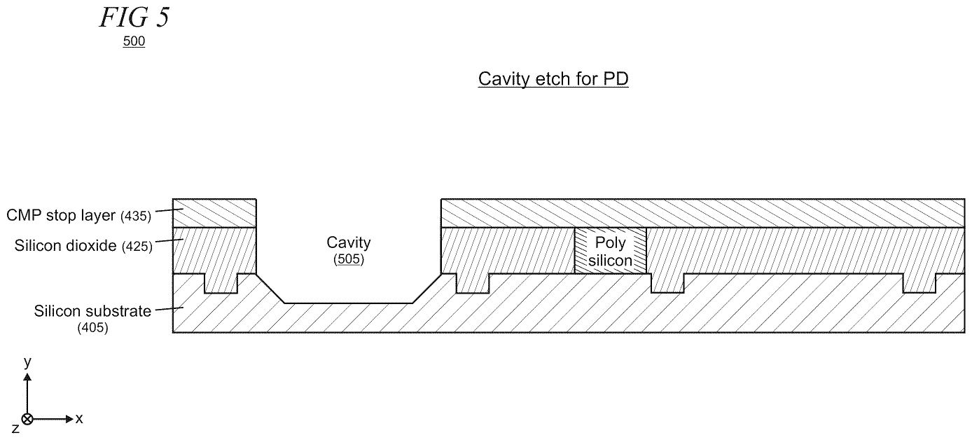

FIG. 5 shows a step 500 in a first stage of the present two-stage manufacturing of EAMs and PDs. The first stage includes fabrication of a PD. In step 500 of the first stage, a cavity 505 is created in the PIC structure 400 which extends through the CMP stop layer 435 and the silicon dioxide layer 425 and into the first rib waveguide 415 formed in the silicon substrate 405. The cavity is generally formed in the starting PIC structure using photolithography and etching processes. The cavity includes a trapezoidal lower portion in this illustrative implementation, as shown, but any shape created by the cavity etch may be utilized in other implementations. In some embodiments, the cavity etching for the PD extends through a polysilicon layer or polysilicon element when such materials are utilized.

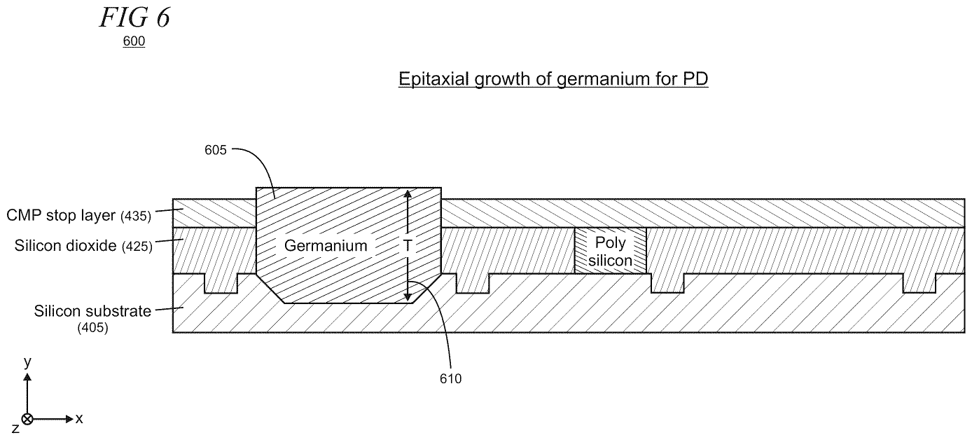

FIG. 6 shows a step 600 in the first stage of manufacturing in which an epitaxial structure 605 for a PD is grown using germanium. Step 600 includes preparing the cavity in the substrate of the starting PIC structure 400 to ensure clean, contamination-free surfaces. In some implementations, a relatively thin germanium buffer layer (not shown) may be deposited in the exposed cavity to help manage lattice mismatch between the germanium and silicon substrate. The epitaxial growth of the buffer and/or main germanium layers in the cavity may be performed, for example, using CVD or molecular beam epitaxy (MBE).

In some cases, the buffer layer is grown at a low temperature while the main growth is performed at a relatively higher temperature. In some cases, post-growth processing may be utilized, such as annealing or thermal cycling, to reduce defects and control tensile strain in the germanium PD to tune its performance.

The thickness in the y-direction, T (indicated by reference numeral 610), of the germanium epitaxial structure 605 after performance of the germanium epitaxial growth step 600 may be greater, in some implementations, over that utilized in conventional single-stage EAM and PD manufacturing. This increased thickness provides additional robustness for the germanium to protect it during downstream processing.

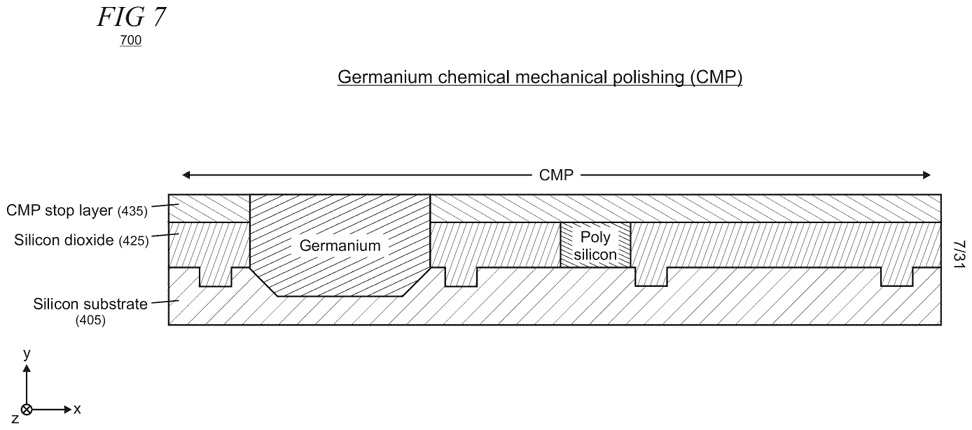

FIG. 7 shows a step 700 in the first stage of manufacturing in which the germanium epitaxial structure grown in the prior step is subjected to a CMP process. The CMP process removes excess material from the germanium structure to achieve a planar surface with the top surface of the CMP stop layer 435 at the top of the PIC structure. The CMP process for germanium typically uses a mixture of commercial CMP slurries designed for oxide and metal polishing. The specific composition may vary depending on the desired removal rates and surface quality. After the CMP process, a thorough post-CMP cleaning is performed to remove any residual slurry particles and prevent contamination of subsequent downstream fabrication steps.

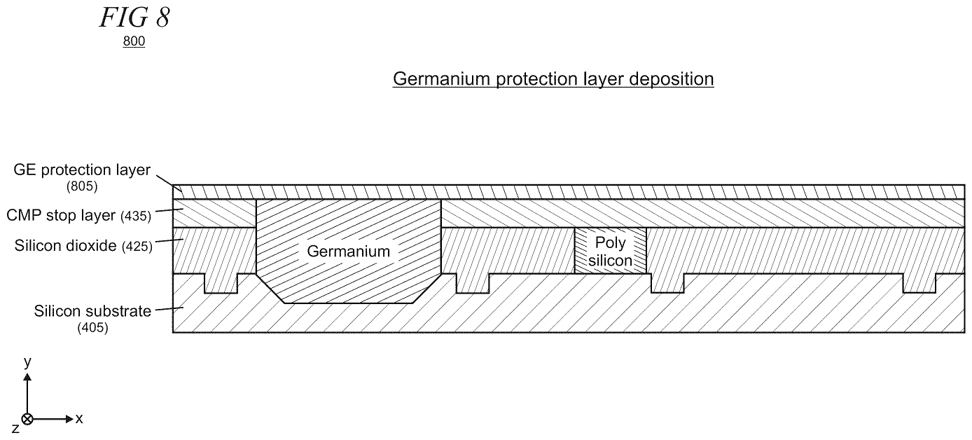

FIG. 8 shows a step 800 in the first stage of manufacturing in which a protection layer 805 for the grown germanium epitaxial structure is deposited as the top layer of the PIC structure to protect the germanium during subsequent processing steps in the second stage of the present two-stage manufacturing. The protection layer may comprise silicon dioxide in a relatively thin layer (e.g., 50 nm) to minimize the impact of the germanium from subsequent thermal processing. The silicon dioxide in the protection layer further serves as a mask for selective epitaxial growth. Dielectric materials are typically chosen as protection layers, however, in some implementations, the protection layer may comprise an encapsulation layer of silicon.

FIG. 9 shows a step 900 in a second stage of the present two-stage manufacturing of EAMs and PDs. The second stage includes fabrication of an EAM. In step 900 in the second stage, a cavity 905 is created in the PIC structure which extends through the GE protection layer 805, CMP stop layer 435, silicon dioxide layer 425, and into the second rib waveguide 420 formed in the silicon substrate 405. The cavity is generally formed in the starting PIC structure using photolithography and etching processes in a similar manner as with the PD cavity, as described above. The cavity includes a trapezoidal lower portion in this illustrative implementation, as shown, but any shape created by the cavity etch may be utilized in other implementations.

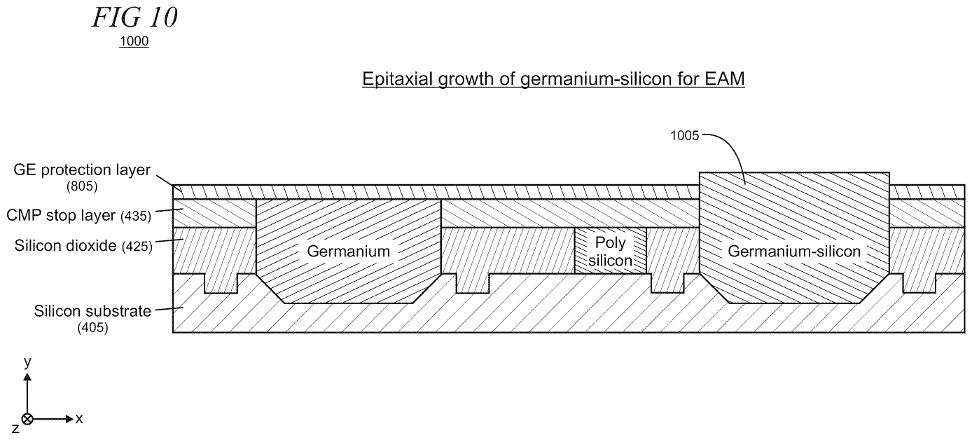

FIG. 10 shows a step 1000 in the second stage of manufacturing in which an epitaxial structure 1005 for an EAM is grown using a germanium-silicon alloy. Step 1000 includes preparing the cavity in the substrate of the starting structure to ensure clean, contamination-free surfaces. In some implementations, a relatively thin germanium or germanium-silicon alloy buffer layer (not shown) may be deposited in the exposed cavity to help manage lattice mismatch between the germanium-silicon and silicon substrate. The epitaxial growth of the buffer and/or main germanium-silicon layers in the cavity may be performed, for example, using CVD or MBE.

The use of separate epitaxial growth steps in the two-step manufacturing for the germanium PD and germanium-silicon EAM devices is in recognition that the devices are distinct with regard to material, structure, and function. Accordingly, the conditions for epitaxial growth may be optimized for the individual devices under the present principles.

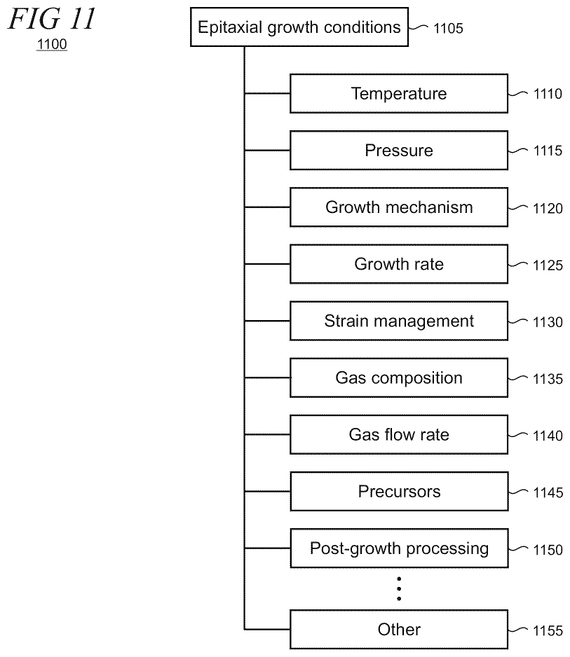

FIG. 11 shows an illustrative taxonomy 1100 of exemplary epitaxial growth conditions 1105 that may be varied, tailored, and/or optimized to suit the separate fabrication of the PD and EAM devices using the present two-stage manufacturing. It is emphasized that such growth variables depicted in FIG. 11 and described herein are intended to be illustrative only and should not be construed as limiting the scope of the invention. While specific examples of growth conditions are provided, it is to be understood that the PD and EAM may be separately epitaxially grown under conditions that are not explicitly shown or described, as would be apparent to one skilled in the art upon review of this disclosure.

As shown, epitaxial growth conditions 1105 illustratively include: temperature 1110, pressure 1115, growth mechanism 1120, growth rate 1125, strain management 1130, gas composition 1135, gas flow rate 1140, precursors 1145, post-growth processes 1150, and other suitable growth conditions 1155. Optimizing one or more of these growth conditions, individually or in various combinations, for each manufacturing stage can provide high-quality epitaxial structures for the PD and EAM epitaxial structures with fewer defects in many applications.

Germanium typically requires lower growth temperatures compared to Germanium-silicon to minimize surface roughening and interdiffusion at the interface between the germanium and silicon substrates. Lower pressures are typically used for germanium as compared with relatively higher pressures for germanium-silicon which helps promote relaxation of built-in strain to reduce defects. Utilization of the separate stages under the present principles facilitates optimizing pressures to achieve the desired epitaxial composition, layer thickness, and relaxation. Growth parameters like temperature, pressure, and growth rate can influence the relaxation process.

Growth mechanisms for germanium and germanium-silicon can differ where germanium can form three-dimensional islands (i.e., Stranski-Krastanov growth mode) on the silicon substrate while germanium-silicon is generally growable in a two-dimensional layer-by-layer mode, particularly at lower germanium concentrations in the alloy. Providing conditions for these different growth modes individually to achieve smooth, continuous layers of the materials using the present two-stage manufacturing principles is more straightforward with fewer challenges when compared to simultaneous growth with conventional single-stage epitaxial manufacturing techniques.

Germanium tends to have a faster growth rate compared to germanium-silicon. For germanium-silicon, the growth rate generally depends on the alloy composition, with higher germanium content typically resulting in faster growth. In conventional single-stage manufacturing, balancing the growth rates for the different PD and EAM structures requires a compromise that is not experienced when implementing the present two-stage manufacturing.

Germanium on silicon experiences a relatively large lattice mismatch which typically requires careful strain management during device fabrication. By contrast, germanium-silicon alloys can provide for graded compositions that enable lattice mismatch to be accommodated more gradually.

The composition of the gases used during the epitaxial growth process directly affects the chemical reactions that occur on the substrate surface. The right balance of these gases is essential to achieving optimal growth conditions and desired material properties. Flow rates of the gases also impact the dynamics within the growth chamber. Higher flow rates can enhance mass transport to the substrate, which can lead to increased growth rates. However, if not controlled properly, it may also introduce turbulence or non-uniformities in the deposited layers. Adjusting flow rates can optimize conditions for diffusion and reaction kinetics, ultimately affecting the thickness and uniformity of the epitaxial layers. Thus, both gas composition and flow rates are critical parameters in controlling epitaxial growth processes, influencing not only the growth rate but also the structural and electronic properties of the resulting materials.

Precursors are the starting chemical compounds used to supply the atoms or molecules needed for epitaxial growth. They are the source materials that decompose or react to form the desired epitaxial layer. Gas composition, as discussed above, refers to the overall mixture of gases present in the reaction chamber during epitaxial growth including precursor gases, carrier gases, dopant gases (when doping is utilized), and any by-products from precursor decomposition. Accordingly, the gas composition can change throughout the growth process as precursors decompose and react. While precursors determine the initial gas inputs, the overall gas composition evolves during the growth process. Epitaxial growth techniques involve controlling both the precursor flow and the resulting gas composition to achieve high-quality layers. Finding compatible chemistries and optimizing gas flows to achieve desired compositions and growth rates for each material individually is less complex under the present two-stage manufacturing compared to conventional single-stage manufacturing.

Post-growth processes are another example of variable conditions that may be separately optimized per epitaxial structure using the present two-stage manufacturing. These include, for example, thermal annealing, cyclical annealing, hydrogen annealing, ion implantation and annealing, rapid thermal annealing, CMP, selective etching, laser annealing, and post-growth oxidation. These post-growth processes can be used individually or in combination to tailor the properties of epitaxial layers for specific applications, such as improving crystal quality, modifying strain states, or enhancing optical and other characteristics of the resulting device structures.

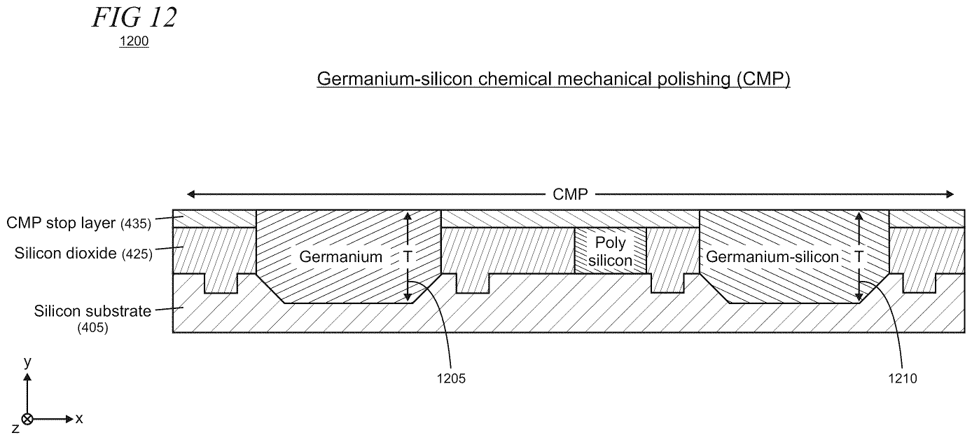

FIG. 12 shows a step 1200 in the second stage of manufacturing in which a CMP process is utilized to remove a portion of the germanium-silicon structure grown in the prior step 1100 (FIG. 11) as well as the germanium protection layer 805 that was deposited in step 800 in the first stage of manufacturing (FIG. 8). The CMP process is performed to bring the germanium and germanium-silicon epitaxial structures to substantially the same overall thickness, T, respectively indicated by reference numerals 1205 and 1210. This thickness is approximately the target thickness that would be realized using a conventional single-stage manufacturing process.

The CMP process in the second stage of manufacturing subjects the germanium epitaxial structure to a second polishing. However, the risks of over-polishing and/or excess material removal are mitigated by the increased thickness 610 (FIG. 6) provided for the germanium epitaxial structure, as discussed above. In addition, sufficient CMP process controls, optimization of polishing parameters, and post-CMP inspection and metrology may be implemented in typical manufacturing environments to detect indications of potential over-polishing.

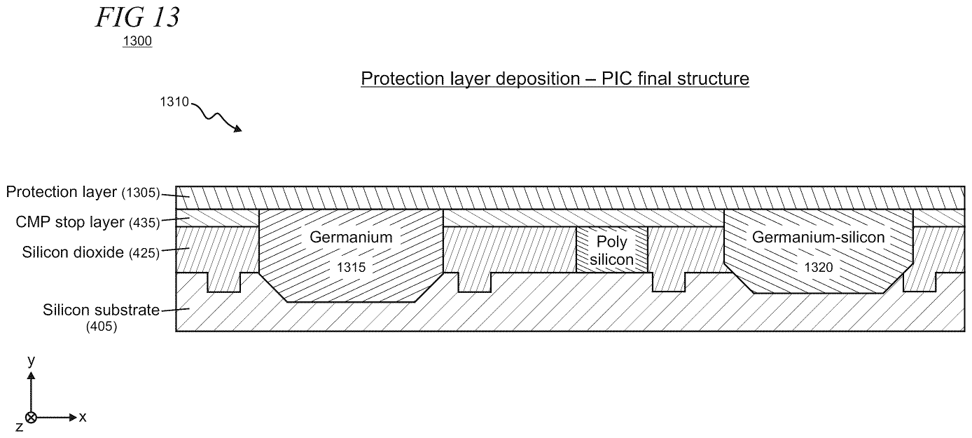

FIG. 13 shows a step 1300 in the second stage of manufacturing in which a protection layer 1305 is deposited to complete the final PIC structure 1310. Suitable materials for the protection layer include silicon oxide and silicon dioxide which are commonly deposited via CVD. Other materials, such as aluminum oxide, may be alternatively utilized for the protection layer, deposited using atomic layer deposition (ALD). Amorphous silicon is also suitable to protect germanium and germanium-silicon surfaces. In addition, a combination of materials may be used in a stack to optimize protection and device performance.

It may be appreciated that the drawing shows an elevation view of the end surfaces of the PD and EAM, as respectively indicated by reference numerals 1315 and 1320. The ends of the PD and EAM are configurable as input or output ports. For example, if the ends of the PD and EAM shown in the drawing are utilized for input ports, then the opposite ends are utilized for output ports, or vice versa.

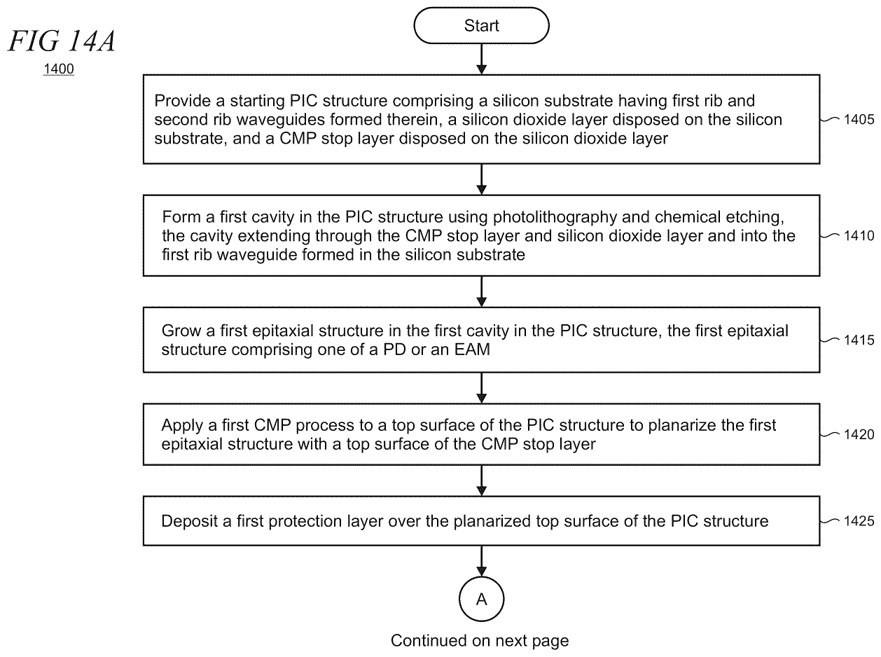

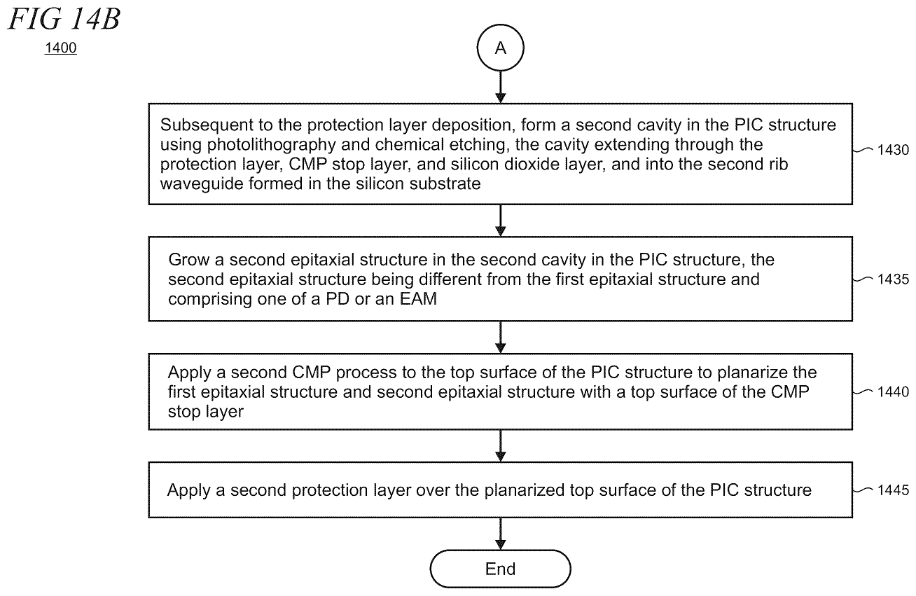

FIGS. 14A and 14B show a flowchart 1400 of an illustrative method for fabricating a PD and an EAM on a unitary silicon substrate for use in a PIC using a two-stage manufacturing process. Block 1405 includes providing a starting PIC structure comprising a silicon substrate having first and second rib waveguides formed therein, a silicon dioxide layer disposed on the silicon substrate, and a CMP stop layer disposed on the silicon dioxide layer.

Block 1410 includes forming a first cavity in the PIC structure using photolithography and chemical etching, the cavity extending through the CMP stop layer and silicon dioxide layer and into the first rib waveguide formed in the silicon substrate. Block 1415 includes growing a first epitaxial structure in the first cavity in the PIC structure, the first epitaxial structure comprising one of a PD or EAM.

Block 1420 includes applying a first CMP process to a top surface of the PIC structure to planarize the first epitaxial structure with a top surface of the CMP stop layer. Block 1425 includes depositing a first protection layer over the planarized top surface of the PIC structure.

Block 1430 includes, subsequent to the protection layer deposition, forming a second cavity in the PIC structure using photolithography and chemical etching, the cavity extending through the protection layer, CMP stop layer, and silicon dioxide layer, and into the second rib waveguide formed in the silicon substrate. Block 1435 includes growing a second epitaxial structure in the second cavity in the PIC structure, the second epitaxial structure being different from the first epitaxial structure and comprising one of a PD or an EAM.

Block 1440 includes applying a second CMP process to the top surface of the PIC structure to planarize the first epitaxial structure and second epitaxial structure with a top surface of the CMP stop layer. Block 1445 includes applying a second protection layer over the planarized top surface of the PIC structure.

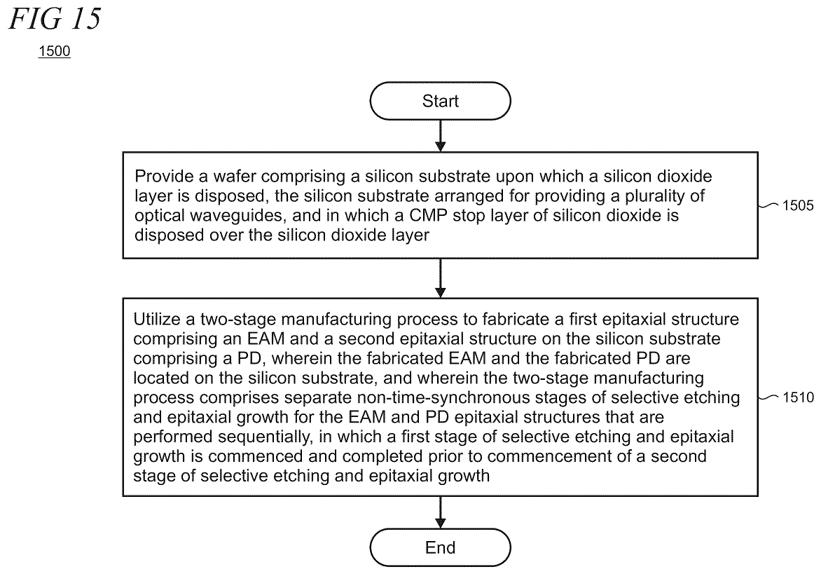

FIG. 15 is a flowchart 1500 of an illustrative method for fabricating epitaxial structures on a wafer for a photonic interface. Block 1505 includes providing a wafer comprising a silicon substrate upon which a silicon dioxide layer is disposed, the silicon substrate arranged for providing a plurality of optical waveguides, and in which a CMP (chemical mechanical polishing) stop layer of silicon dioxide is disposed over the silicon dioxide layer.

Block 1510 includes utilizing a two-stage manufacturing process to fabricate a first epitaxial structure comprising an EAM and a second epitaxial structure on the silicon substrate comprising a PD, wherein the fabricated EAM and the fabricated PD are located on the silicon substrate, and wherein the two-stage manufacturing process comprises separate non-time-synchronous stages of selective etching and epitaxial growth for the EAM and PD epitaxial structures that are performed sequentially, in which a first stage of selective etching and epitaxial growth is commenced and completed prior to commencement of a second stage of selective etching and epitaxial growth.

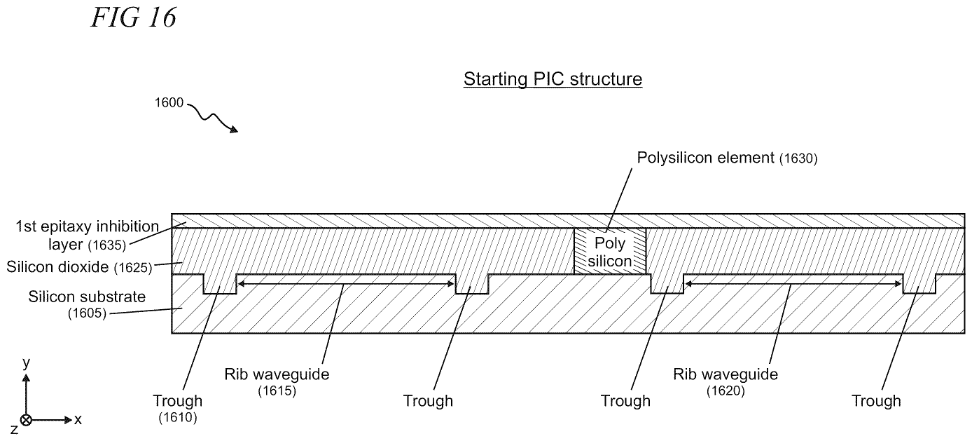

FIGS. 16-24 show sequential steps in a second illustrative embodiment of a two-stage manufacturing process for a PD and an EAM that are epitaxially grown on a unitary silicon chip in accordance with the present principles, in which CMP is not utilized. FIG. 16 shows a second illustrative embodiment of a PIC structure 1600 comprising a silicon substrate 1605 that is provided as a starting point for the two-stage manufacturing. The starting PIC structure is usable as a component in the PIC 204, shown in FIG. 2 and described above, after various manufacturing processes are completed.

The starting PIC structure 1600 is similar to the starting PIC structure 400 shown in FIG. 4 and described in the accompanying text above in the first illustrative embodiment of two-stage manufacturing. However, as CMP is not utilized in the second illustrative embodiment of two-stage manufacturing, the starting PIC structures 400 and 1600 are different, as discussed below.

The starting PIC structure 1600 comprises a silicon substrate 1605 that includes a plurality of troughs (representatively indicated by reference numeral 1610) used to form rib waveguides 1615 and 1620 in the substrate. A silicon dioxide layer 1625 providing a dielectric function is deposited on the silicon substrate 1605 using manufacturing techniques such as thermal oxidation or CVD. The silicon dioxide layer has a refractive index that differs from that of the silicon substrate to thus function as cladding for the rib waveguides 1615 and 1620.

An exemplary polysilicon element 1630 is disposed on the silicon substrate 1605. As in the first embodiment, the polysilicon element may be utilized in the completed PIC (e.g., PIC 204 in FIG. 2) for enhanced optical coupling between the silicon waveguide and the germanium absorption region of the PD.

Rather than utilize a CMP stop layer, as with the first embodiment discussed above, the starting PIC structure 1600 utilizes an epitaxy inhibiting material that is deposited in relatively thin layers, including first and second layers, as discussed further below. The epitaxy inhibiting layers each provide a barrier to prevent respective epitaxial growth of germanium and germanium-silicon in some areas of the PIC to thereby facilitate selective area epitaxy growth in other areas. An exemplary epitaxy inhibiting material is TEOS oxide which is silicon dioxide deposited using tetraethyl orthosilicate (TEOS) as a precursor. TEOS oxide provides high-quality oxide films for the PIC structure using vapor deposition processes such as CVD. As shown in FIG. 16, the starting PIC structure 1600 includes a first epitaxy inhibition layer 1635.

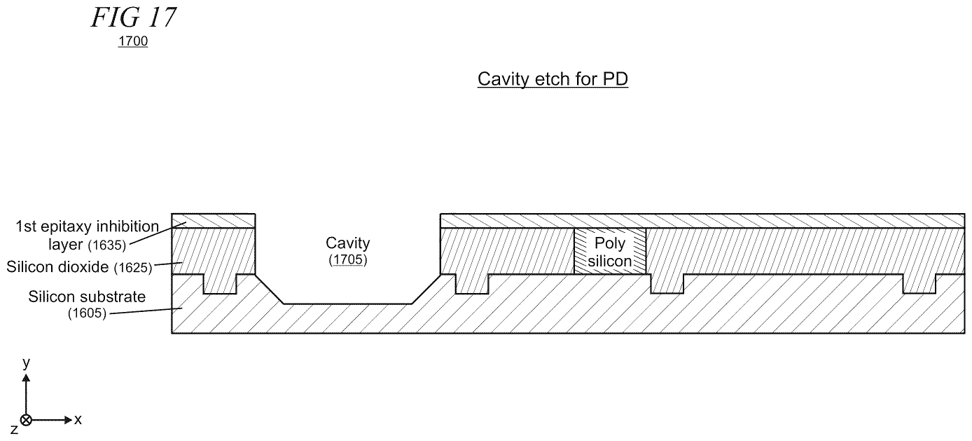

FIG. 17 shows a step 1700 in a first stage for the second embodiment of the present two-stage manufacturing of EAMs and PDs. The first stage includes fabrication of a PD. In step 1700, a cavity 1705 is created in the PIC structure 1600 which extends through the first epitaxy inhibition layer 1635 and silicon dioxide layer 1625 and into the first rib waveguide 1615 formed in the silicon substrate 1605. The cavity is generally formed in the starting PIC structure using photolithography and etching processes. The cavity includes a trapezoidal lower portion in this illustrative implementation, as shown, but any shape created by the cavity etch may be utilized in other implementations. In some embodiments, the cavity etching for the PD extends through a polysilicon layer or polysilicon element when such materials are utilized.

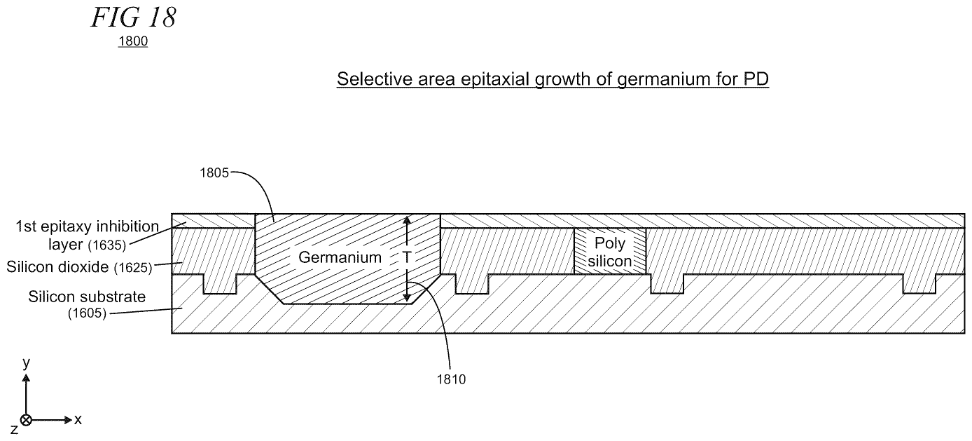

FIG. 18 shows a step 1800 in the first stage of manufacturing in which an epitaxial structure 1805 for a PD using germanium is grown using selective area epitaxy. Step 1800 includes preparing the cavity in the substrate of the starting PIC structure 1600 to ensure clean, contamination-free surfaces. In some implementations, a relatively thin germanium buffer layer (not shown) may be deposited in the exposed cavity to help manage lattice mismatch between the germanium and silicon substrate.

The selective area epitaxial growth of the buffer and/or main germanium layers in the cavity may be performed, for example, using CVD or MBE. Crystal growth on the PIC structure is prevented in the area covered by the epitaxy inhibition layer 1635 while growth is allowed in the exposed cavity 1705 (FIG. 17) (i.e., the cavity is the “selected area” for epitaxial growth). The use of the epitaxy inhibition layer, in combination with control of growth conditions (e.g., as shown in FIG. 11 above), enables precise control over the location, shape, film thicknesses, and other properties of the grown epitaxial structures.

In some cases, the buffer layer is grown at a low temperature while the main growth is performed at a relatively higher temperature. In some cases, post-growth processing may be utilized, such as annealing or thermal-cycling, to reduce defects and control tensile strain in the germanium structure to tune its performance. The thickness in the y-direction, T (indicated by reference numeral 1810), of the germanium epitaxial structure 1805 after performance of the selective area epitaxial growth step 1800 is approximately the same as the thickness utilized for the structure when employing a conventional single-stage EAM and PD manufacturing process.

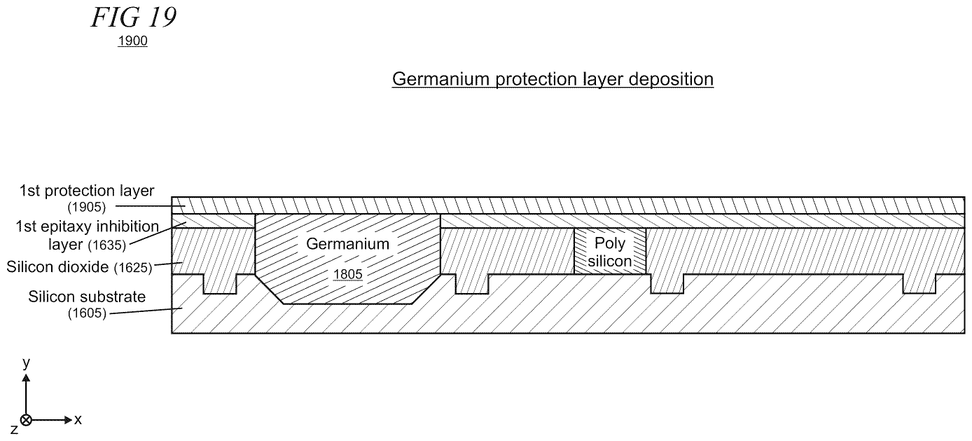

FIG. 19 shows a step 1900 in the first stage of manufacturing in which a first protection layer 1905 for the selective area epitaxially grown germanium structure is deposited as the top layer of the PIC structure. The first protection layer is arranged to protect the germanium during subsequent processing steps in the second stage of the present two-stage manufacturing. The first protection layer may comprise materials and be deposited as described above with reference to FIG. 13. The first protection layer is provided with approximately the same thickness utilized when employing a conventional single-stage EAM and PD manufacturing process.

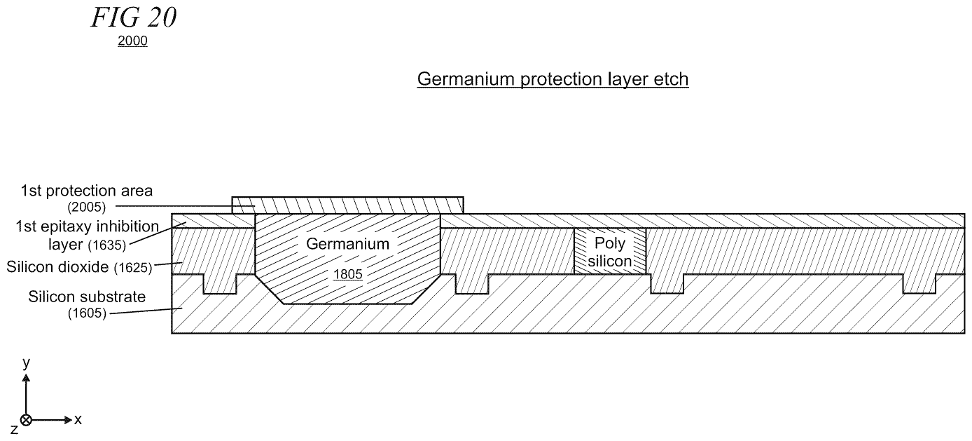

FIG. 20 shows a step 2000 in the first stage of manufacturing in which the first protection layer 1905 deposited in the preceding step is selectively etched away so that only a portion 2005 of the first protection layer remains. The remaining portion 2005 is located over the germanium structure 1805 as shown. In some cases, some of first epitaxy inhibition layer 1635 may also be removed during the etching step.

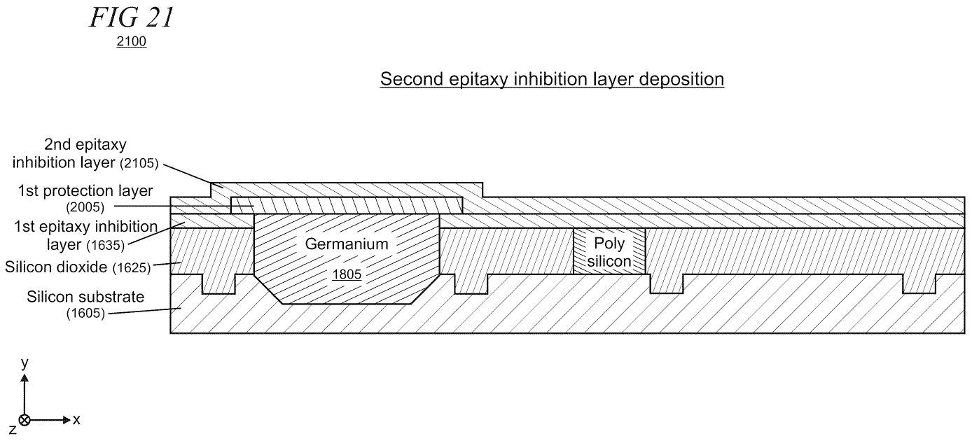

FIG. 21 shows a step 2100 in the first stage of manufacturing in which a second epitaxy inhibition layer 2105 is deposited over the PIC structure. The second epitaxy inhibition layer is configured as a conformal layer over the protection area portion 2005 and the first epitaxy inhibition layer 1635. It is noted that the first and second epitaxy inhibition layers 1635 and 2105 are shown as separate layers for purposes of describing the methods and processes in the present two-stage manufacturing. However, as each of the first and second epitaxy inhibition layers comprise thin films of silicon dioxide, they may be structurally and functionally considered as a unitary structure.

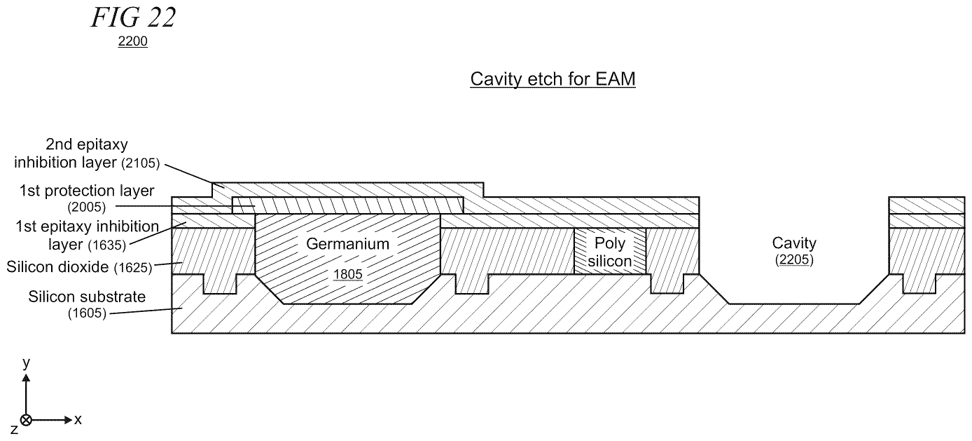

FIG. 22 shows a step 2200 in a second stage of the present two-stage manufacturing of EAMs and PDs. The second stage includes fabrication of an EAM. In step 2200 in the second stage, a cavity 2205 is created in the PIC structure which extends through the combined first and second epitaxy inhibition layers 2105 and 1635, the silicon dioxide layer 1625, and into the second rib waveguide 1620 formed in the silicon substrate 1605. The cavity is generally formed in the starting PIC structure using photolithography and etching processes in a similar manner as with the PD cavity, as described above. The cavity includes a trapezoidal lower portion in this illustrative implementation, as shown, but any shape created by the cavity etch may be utilized in other implementations.

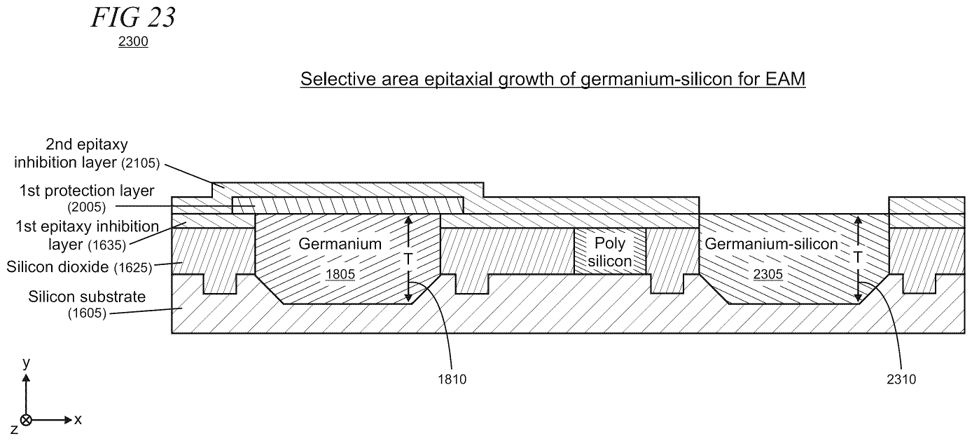

FIG. 23 shows a step 2300 in the second stage of manufacturing in which an epitaxial structure 2305 for an EAM using a germanium-silicon alloy is grown using selective area epitaxy. Step 2300 includes preparing the cavity in the substrate of the PIC structure to ensure clean, contamination-free surfaces. In some implementations, a relatively thin germanium or germanium-silicon alloy buffer layer (not shown) may be deposited in the exposed cavity to help manage lattice mismatch between the germanium-silicon and silicon substrate. The selective area epitaxial growth of the buffer and/or main germanium-silicon layers in the cavity may be performed, for example, using CVD or MBE

The germanium epitaxial structure 1805 and germanium-silicon epitaxial structure 2305 have substantially the same overall thickness, T, respectively indicated by reference numerals 1810 and 2310. This thickness is approximately the target thickness that would be realized using a conventional single-stage manufacturing process.

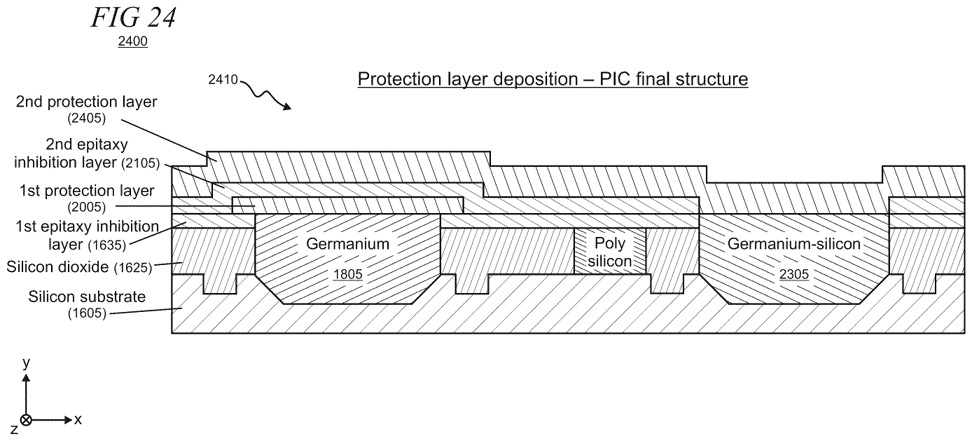

FIG. 24 shows a step 2400 in the second stage of manufacturing in which a second protection layer 2405 is deposited as a conformal layer to complete the final PIC structure 2410. The second protection layer may comprise materials and be deposited as described above with reference to FIG. 13.

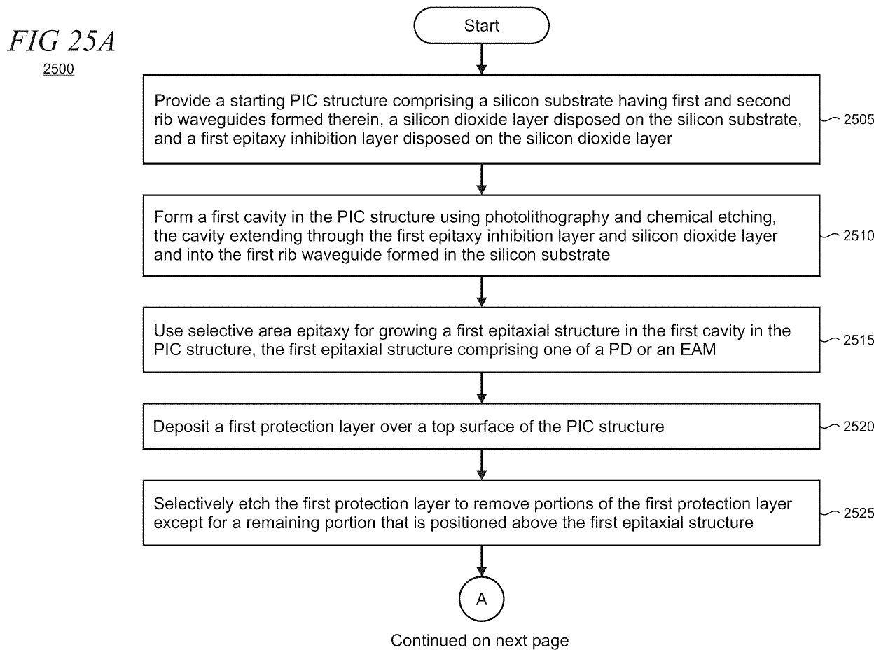

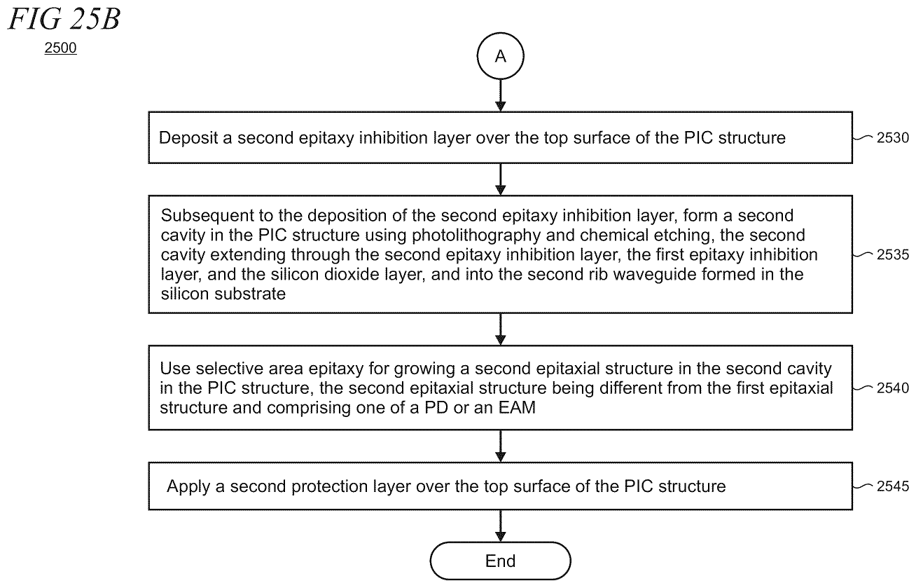

FIGS. 25A and 25B show a flowchart 2500 of an illustrative method for fabricating a PD and an EAM on a unitary silicon substrate for use in a PIC using a two-stage manufacturing process. Block 2505 includes providing a starting PIC structure comprising a silicon substrate having first and second rib waveguides formed therein, a silicon dioxide layer disposed on the silicon substrate, and a first epitaxy inhibition layer disposed on the silicon dioxide layer.

Block 2510 includes forming a first cavity in the PIC structure using photolithography and chemical etching, the cavity extending through the first epitaxy inhibition layer and silicon dioxide layer and into the first rib waveguide formed in the silicon substrate. Block 2515 includes using selective area epitaxy for growing a first epitaxial structure in the first cavity in the PIC structure, the first epitaxial structure comprising one of a PD or an EAM.

Block 2520 includes depositing a first protection layer over a top surface of the PIC structure. Block 2525 includes selectively etching the first protection layer to remove portions of the first protection layer except for a remaining portion that is positioned above the first epitaxial structure.

Block 2530 includes depositing a second epitaxy inhibition layer over the top surface of the PIC structure. Block 2535 includes, subsequent to the deposition of the second epitaxy inhibition layer, forming a second cavity in the PIC structure using photolithography and chemical etching, the second cavity extending through the second epitaxy inhibition layer, the first epitaxy inhibition layer, and the silicon dioxide layer, and into the second rib waveguide formed in the silicon substrate.

Block 2540 includes using selective area epitaxy for growing a second epitaxial structure in the second cavity in the PIC structure, the second epitaxial structure being different from the first epitaxial structure and comprising one of a PD or an EAM. Block 2545 includes applying a second protection layer over the top surface of the PIC structure.

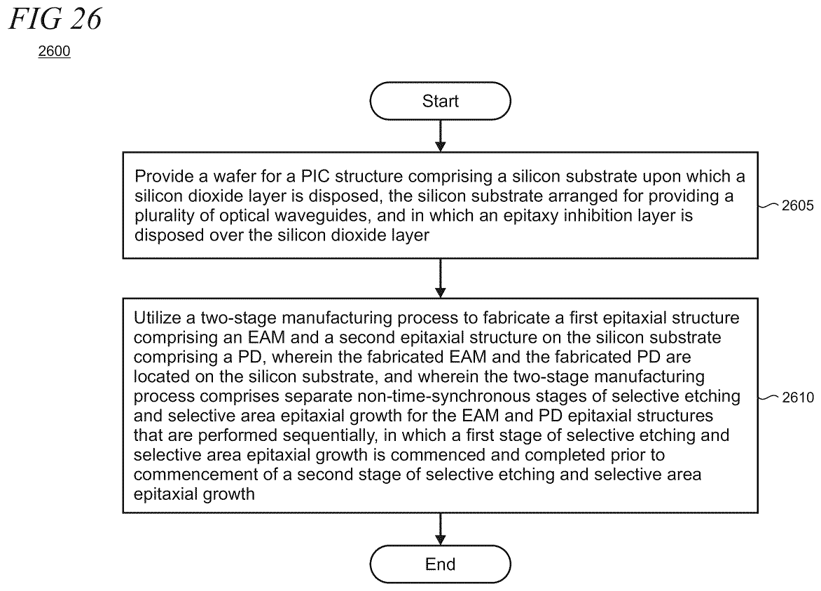

FIG. 26 is a flowchart 2600 of an illustrative method for fabricating epitaxial structures on a wafer for a photonic interface. Block 2605 includes providing a wafer for a photonic integrated circuit (PIC) structure comprising a silicon substrate upon which a silicon dioxide layer is disposed, the silicon substrate arranged for providing a plurality of optical waveguides, and in which an epitaxy inhibition layer is disposed over the silicon dioxide layer.

Block 2610 includes utilizing a two-stage manufacturing process to fabricate a first epitaxial structure comprising an electro-absorption modulator (EAM) and a second epitaxial structure on the silicon substrate comprising a photodiode (PD), wherein the fabricated EAM and the fabricated PD are located on the silicon substrate, and wherein the two-stage manufacturing process comprises separate non-time-synchronous stages of selective etching and selective area epitaxial growth for the EAM and PD epitaxial structures that are performed sequentially, in which a first stage of selective etching and selective area epitaxial growth is commenced and completed prior to commencement of a second stage of selective etching and selective area epitaxial growth.

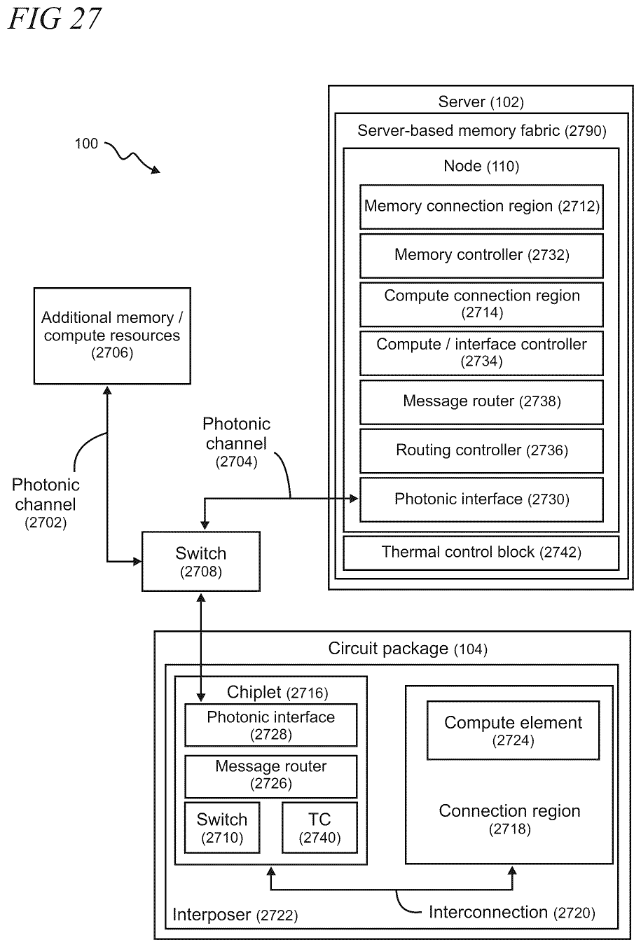

FIG. 27 shows a more detailed example of the system 100 shown in FIG. 1 and described in the accompanying text. In particular, FIG. 27 shows an illustrative example of a server-based memory fabric 2790 that uses circuit packages to move data within the memory fabric (e.g., to/from compute elements and memory/compute resources).

As shown, the system 100 includes a server 102, additional memory/compute resources 2706, a switch 2708, and a circuit package 104. The server 102 includes the node 110. While not shown, the system 100 and/or the server 102 may include additional nodes extending in one or more dimensions. As shown, the node 110 includes a memory connection region 2712, a memory controller 2732, a compute connection region 2714, an interface controller 2734 (e.g., a memory and/or compute interface controller), a message router 2738 (i.e., a router), a routing controller 2736, a photonic interface 2730, and a thermal control block 2742.

As also shown, the node 110 (e.g., server 102) connects to the circuit package 104 and the switch 2708 via a photonic channel 2704. The circuit package 104 includes an interposer 2722 that connects a chiplet 2716 and compute element 2724 via an interconnection 2720 and/or connection region 2718. In FIG. 27, the chiplet 2716 includes a photonic interface 2728, a message router 2726, a switch 2710, and a thermal control block 2740. Further, the circuit package 104 and the server 102 connect to the additional memory/compute resources 2706 via the switch 2708 using a photonic channel 2702, as shown.

In an illustrative example, the circuit package 104 is connected via photonic channels (e.g., photonic channel 2702 and photonic channel 2704) to the server 102 and the additional memory/compute resources 2706. Switches (e.g., switch 2708 or switch 2710) are used to determine when to use a photonic channel, and thus whether circuit package 104 accesses the server-based memory fabric 2790 on the server 102 or additional memory/compute resources 2706.

While FIG. 27 is simplified to show a single node (i.e., node 110) on the server 102, in some implementations, a chip on the server 102 includes hundreds of nodes. Additionally, a multi-chip configuration could have hundreds of thousands of nodes (or more) connected via photonic channels in an n-dimensional memory fabric. In these instances, each of the nodes could have the features of the node 110, including a memory connection region 2712 and/or a compute connection region 2714.

The memory connection region 2712 and the compute connection region 2714 are designed to provide a standard interface for a compute element or a memory element that integrates into the system 100. The memory connection region 2712 and the compute connection region 2714 are configured to receive a memory element or compute element using electrical connections such as copper wires, bump attach units, copper pillars, through-silicon vias, and/or other connections.

Examples of memory elements include, but are not limited to, NAND Flash memory, solid-state drive (SSD) memory, NOR Flash memory, complementary metal-oxide-semiconductor (CMOS) memory, thin film transistor-based memory, phase change memory (PCM), storage class memory (SCM), read-only memory (ROM), random-access memory (RAM), magneto-resistive RAM (MRAM), resistive RAM, static random access memory (SRAM), dynamic RAM (DRAM), synchronous dynamic random-access memory (SDRAM), Double Data Rate (DDR)-based DRAM, high bandwidth memory (HBM), and dual in-line memory module (DIMM) memory.

Examples of compute elements include, but are not limited to, CPUs, GPUs, MPUs, tensor engines, load units, store units, neural compute engines, dot-products, convolution engines, field-programmable gate arrays (FPGAs), and/or AI accelerators.

The circuit package 104 includes a chiplet 2716 and a connection region 2718 connected via interconnection 2720. In an illustrative example, the chiplet 2716 has a bottom surface that is coupled to the connection region 2718 via an electrical connection through the interposer 2722. In some instances, the interconnection 2720 can serve as the electrical connection. Additionally, the interconnection 2720 is a standard electrical connection that passes through an interposer 2722. The interconnection 2720 includes multiple channels, which correspond with multiple ports in either the memory connection region 2712 or the compute connection region 2714.

A compute element 2724 can be attached to the connection region 2718 using various means. The chiplet 2716 further includes a message router 2726 for controlling the flow of packets between the chiplet and the rest of the system 100. For example, the router forms digital packets that include message requests from compute elements as well as corresponding routing information. The photonic interface 2728 on the circuit package 104 and the photonic interface 2730 on the node 110 form an optical bi-directional path for an optical signal that represents the digital packet and can be reconstructed and/or transformed to a digital form when routed between the server 102 and the circuit package 104 to an electrical port of a message router at the final destination.

Although not specifically shown in FIG. 27, the photonic interfaces commonly include photonic transceivers having both transmit units and receive units. In various instances, transmit units convert a digital packet into an optical signal and transmit it across a photonic channel. Likewise, receive units convert the optical signal into a digital packet and transmit it across an electrical channel. For example, the photonic interface 2728 in the circuit package 104 utilizes a transmit unit to connect to a receive unit in the photonic interface 2730 of the node 110 via a first photonic channel and a transmit unit in photonic interface 2730 of the node 110 connects to a receive unit in photonic interface 2728 of the circuit package 104 via a second photonic channel. This enables bidirectional optical communications between circuit package 104 and the server 102.

In some implementations, within the router, a transmit unit is partially in the chiplet 2716 and partially in the interposer 2722. In these instances, the transmit unit transmits a digital packet through an FAU in an optical form to a photonic interface to travel toward the destination indicated in the routing information of the digital packet. Similarly, a receive unit is partially in the chiplet 2716 and partially in the interposer 2722. For example, the receive unit is partially in the chiplet 2716 and partially in the interposer 2722 for receiving an optical signal through the FAU in a digital form at the router.

The circuit package 104 requests an item stored in the memory connection region 2712 of the node 110, and/or utilizes the compute resources available in the compute connection region 2714. In these instances, the photonic interface 2730 receives the request from the circuit package 104 via the photonic channel 2704 and converts the request into a digital packet, which is provided to either a memory controller 2732, an interface controller 2734, or a routing controller 2736.

In an illustrative example, the memory controller 2732 is an electrical interface, such as a Joint Electron Device Engineering Council (JEDEC) compliant or compute express link (CXL) compliant interface that can be used to access a data item stored in a memory element connected in the memory connection region 2712. The interface controller 2734 is an electrical interface, device, or module, that controls and configures the interface of a connected compute element in the compute connection region 2714. The interface controller 2734 performs configurations, handles faults, provides an embodiment of algorithms to transfer data to and from the interface, and/or generates interrupt events to signal the compute connection region 2714 when events relating to the interface occur.

Additionally, the routing controller 2736 is used in a memory fabric where the current node is not the destination node (not shown). In these cases, the routing controller 2736 modifies the digital packet to update the routing information before sending it to a transmit unit connected to an adjacent or next node on the route to the destination node. A message router 2738 transmits the digital packet photonically using one of its optical ports when the current node is not the destination node. The message router 2738 outputs a digital packet along its electrical port when the compute or memory resources are used in the current node.

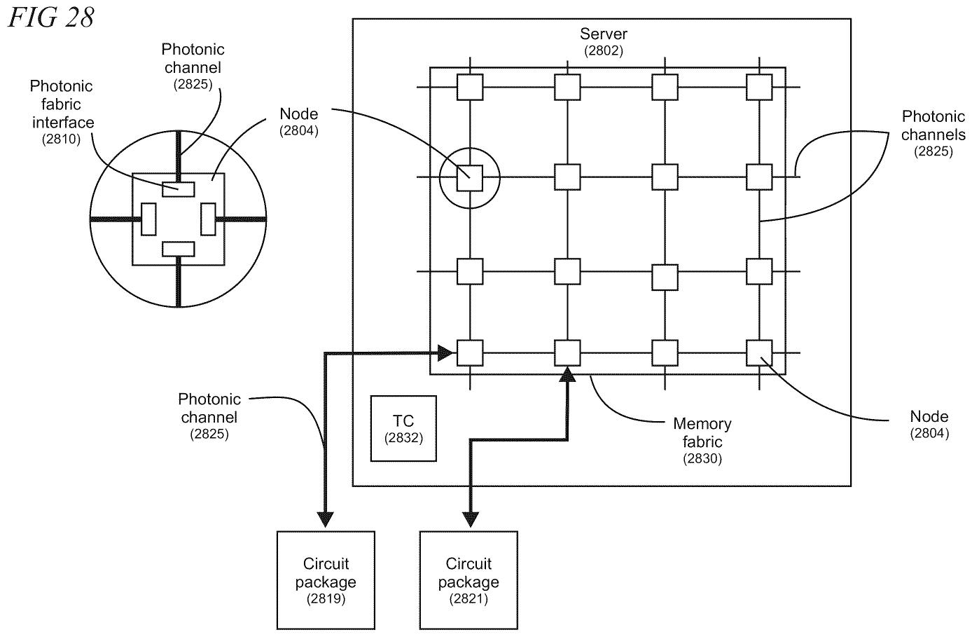

FIG. 28 shows an illustrative arrangement using a memory fabric to connect circuit packages. As shown, the arrangement includes a memory fabric 2830 and circuit packages 2819 and 2821. The memory fabric is shown conceptually from a top view. As shown, the memory fabric is part of a server 2802 and includes multiple nodes 2804, which interconnect via photonic channels 2825. One or more of the multiple nodes 2804 also connect directly to the circuit packages via photonic channels. The photonic channels include inter-chip links and intra-chip links.

As shown, the memory fabric 2830 includes sixteen nodes (i.e., the multiple nodes 2804) arranged in a 4×4, 2-dimensional grid. In other implementations, the memory fabric 2830 is higher dimensional and has additional ports or switches to enable the connection of nodes in n-dimensions. In implementations that use a 4×4 grid for the memory fabric 2830, each of the multiple nodes 2804 has at least four optical ports and one electrical port. In these implementations, the optical ports enable the interconnection of all of the interior nodes using photonic fabric interfaces, as representatively indicated by reference numeral 2810, in the enlarged view of the node on the left side of the drawing. As discussed above with reference to FIGS. 2 and 3, the photonic fabric interfaces are implemented using EAMs and PDs for respective transmit and receive functions. For example, the transmit units and the receive units of adjacent nodes are optically connected by photonic channels to create a bi-directional optical connection between the nodes. Nodes at the periphery of the grid can have an optical port dedicated to the circuit package and/or could be used for inter-chip or intra-chip links to other nodes (not shown). Alternatively, the optical ports on nodes may not be used or not fabricated (e.g., a node has only two or three optical ports), such as a corner node, if the additional ports are not needed.

In various illustrative implementations, each of the multiple nodes 2804 of the memory fabric 2830 includes one or more message routers (not shown) used with the photonic channels 2825 to form an electro-photonic network. In these embodiments, the message routers are arranged in a two-dimensional, quadrilateral array or grid. The message routers of two nodes that are immediately next to each other (e.g., in either horizontal or vertical directions) are connected by a bi-directional channel. In this way, each message router in the interior of the array includes at least four photonic channel interfaces to the at least four respective directional photonic channels (e.g., one for each of the directions that may be referred to as “North,” “South,” “East,” and “West”). Additionally, along the periphery of the array, the routers need only have two (at the corners) or three (at the edges between corners) photonic channel interfaces to serve the memory fabric. In various embodiments, some or all of the photonic channel interfaces at the corner and edge nodes, which are not dedicated to the memory fabric, are used for a point-to-point connection to a circuit package, as shown with respect to circuit package 2819 and circuit package 2821.

The message routers route messages between the circuit packages and the multiple nodes 2804 using various addressing schemes. Regardless of the addressing scheme, the messages may be transferred primarily or exclusively through the memory fabric 2830 via the photonic channels 2825 in the PIC (with optical-to-electrical and electrical-to-optical conversions at each router along the path).

Packet data is provided between the multiple nodes 2804 and/or circuit packages and includes routing information to indicate their destination. For example, a signed 5-bit packet data (e.g., extracted from the header or the payload of a message) provides the relative location (or distance) in the horizontal direction (East/West) to a destination node. In another example, a signed 5-bit packet data provides the relative location (or distance) in the vertical direction (North/South) to the destination node. Packet data of different sizes (e.g., number of bits) may be used, for example, depending on the number of nodes and the resulting size of the address space.

As a message traverses routers to different nodes, the routing information can be modified. For example, the horizontal or vertical coordinate of the routing information is decremented for each hop depending on the dimension along which the message is being transferred. In this example, when the packet data providing the directions to the destination node decrements or decreases to zero, the message has arrived at the destination node. It is then forwarded to a local electrical port of the router in that node for utilization by the compute or memory resources. In some cases, the messages are used to carry read and write memory transactions between nodes or circuit packages.

The server 2802 includes a thermal control block 2832. The thermal control block responds to changes in thermal conditions of the PIC in one or all of the multiple nodes 2804. In one example, the thermal control block cycles through each of the multiple nodes and provides the node's input voltage to the PIC (when needed). For example, the thermal control block provides the input voltages in a magnitude that is designed to return the EAM of the node to peak operating conditions during each time cycle.

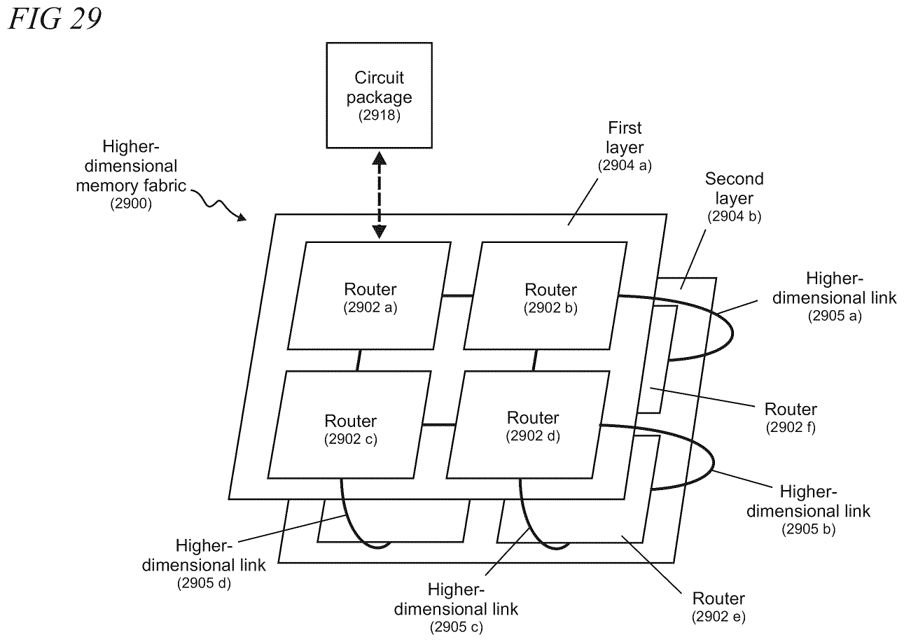

FIG. 29 illustrates a higher-dimensional memory fabric, such as a three-dimensional memory fabric for connecting circuit packages. A perspective view is shown for a higher-dimensional memory fabric 2900 for connecting a circuit package 2918.

The higher-dimensional memory fabric 2900 has multiple layers 2904 including a first layer 2904a and a second layer 2904b. Each of the multiple layers includes routers 2902. In particular, the first layer includes routers 2902a, 2902b, 2902c, and 2902d and the second layer includes 2902e and 2902f.

In this illustrative example, the routers 2902 include optical ports. For example, the optical ports between routers on the first layer 2904a (i.e., the routers 2902a-d) are augmented by higher-dimensional links 2905a, 2905b, 2905c, and 2905d. As shown, the circuit package 2918 connects to the higher-dimensional memory fabric 2900 via one of the routers 2902 a on the first layer. Additionally, depending on the nature and topology of the higher-dimensional memory fabric, any number of additional circuit packages may connect to any number of additional routers and ports.

The higher-dimensional memory fabric 2900 forms a mesh or forms different shapes. Furthermore, the higher-dimensional memory fabric forms a wrapped mesh, a toroid, a wrapped toroid, or an extensible wrapped toroid.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A method of fabricating a photodiode (PD) and electro-absorption modulator (EAM) on a unitary silicon substrate for use in a photonic integrated circuit (PIC) using a two-stage manufacturing process, comprising:
providing a starting PIC structure comprising a silicon substrate having first and second rib waveguides formed therein, a silicon dioxide layer disposed on the silicon substrate, and a first epitaxy inhibition layer disposed on the silicon dioxide layer;
forming a first cavity in the PIC structure using photolithography and chemical etching, the cavity extending through the first epitaxy inhibition layer and silicon dioxide layer and into the first rib waveguide formed in the silicon substrate;
using selective area epitaxy for growing a first epitaxial structure in the first cavity in the PIC structure, the first epitaxial structure comprising one of a PD or an EAM;
depositing a first protection layer over a top surface of the PIC structure;
selectively etching the first protection layer to remove portions of the first protection layer except for a remaining portion that is positioned above the first epitaxial structure;
depositing a second epitaxy inhibition layer over the top surface of the PIC structure;
subsequent to the deposition of the second epitaxy inhibition layer, forming a second cavity in the PIC structure using photolithography and chemical etching, the second cavity extending through the second epitaxy inhibition layer, the first epitaxy inhibition layer, and the silicon dioxide layer and into the second rib waveguide formed in the silicon substrate;
using selective area epitaxy for growing a second epitaxial structure in the second cavity in the PIC structure, the second epitaxial structure being different from the first epitaxial structure and comprising one of a PD or an EAM; and
applying a second protection layer over the top surface of the PIC structure.

2. The method of claim 1 in which the first epitaxy inhibition layer or the second epitaxy inhibition layer comprises tetraethyl orthosilicate (TEOS) oxide.

3. The method of claim 1 in which the first protection layer or second protection layer comprises one of silicon oxide, silicon nitride, or amorphous silicon.

4. The method of claim 1 in which the selective etching of the first protection layer removes a portion of the first epitaxy inhibition layer.

5. The method of claim 1 further comprising post-growth processing comprising one or more of thermal annealing, cyclical annealing, hydrogen annealing, ion implantation and annealing, rapid thermal annealing, chemical mechanical planarization (CMP), selective etching, laser annealing, or post-growth oxidation.

6. A photonic integrated circuit (PIC) epitaxially fabricated using a manufacturing method having two epitaxial growth stages, the method comprising:
providing a starting PIC structure comprising a silicon substrate having first and second rib waveguides formed therein, a silicon dioxide layer disposed on the silicon substrate, and a first epitaxy inhibition layer disposed on the silicon dioxide layer;
forming a first cavity in the PIC structure using photolithography and chemical etching, the cavity extending through the first epitaxy inhibition layer and silicon dioxide layer and into the first rib waveguide formed in the silicon substrate;
using selective area epitaxy for growing a first epitaxial structure in the first cavity in the PIC structure, the first epitaxial structure comprising one of a PD or an EAM;
depositing a first protection layer over a top surface of the PIC structure;
selectively etching the first protection layer to remove portions of the first protection layer except for a remaining portion that is positioned above the first epitaxial structure;
depositing a second epitaxy inhibition layer over the top surface of the PIC structure;
subsequent to the deposition of the second epitaxy inhibition layer, forming a second cavity in the PIC structure using photolithography and chemical etching, the second cavity extending through the second epitaxy inhibition layer, the first epitaxy inhibition layer, and the silicon dioxide layer and into the second rib waveguide formed in the silicon substrate;
using selective area epitaxy for growing a second epitaxial structure in the second cavity in the PIC structure, the second epitaxial structure being different from the first epitaxial structure and comprising one of a PD or an EAM; and
applying a second protection layer over the top surface of the PIC structure.

7. The PIC of claim 6 further comprising a multiplexer/demultiplexer.

8. The PIC of claim 6 further comprising a connection region for electrical connections to a router in an electronic integrated circuit (EIC) and a client compute or memory element.

9. The PIC of claim 6 further comprising a fiber array unit (FAU).

10. The PIC of claim 6 further comprising a thermal control element.

11. The PIC of claim 6 as configured as an interposer.

12. A method for fabricating epitaxial structures on a wafer for a photonic interface, comprising:
providing a wafer for a photonic integrated circuit (PIC) structure comprising a silicon substrate upon which a silicon dioxide layer is disposed, the silicon substrate being arranged for providing a plurality of optical waveguides, and in which an epitaxy inhibition layer is disposed over the silicon dioxide layer; and
utilizing a two-stage manufacturing process to fabricate a first epitaxial structure comprising an electro-absorption modulator (EAM) and a second epitaxial structure on the silicon substrate comprising a photodiode (PD), wherein the fabricated EAM and the fabricated PD are located on the silicon substrate, and
wherein the two-stage manufacturing process comprises separate non-time-synchronous stages of selective etching and selective area epitaxial growth for the EAM and PD epitaxial structures that are performed sequentially, in which a first stage of selective etching and selective area epitaxial growth is commenced and completed prior to commencement of a second stage of selective etching and selective area epitaxial growth.

13. The method of claim 12 in which the EAM is an epitaxial structure comprising a germanium-silicon alloy.

14. The method of claim 12 in which the PD is an epitaxial structure comprising germanium.

15. The method of claim 12 in which growth conditions for each of the epitaxial structures are separately optimized.

16. The method of claim 12 in which the silicon dioxide layer provides cladding for the waveguides.

17. The method of claim 12 in which the waveguide comprises a rib waveguide formed in the silicon substrate using a plurality of trough features in the silicon substrate.

18. The method of claim 12 further comprising configuring the silicon substrate with a polysilicon element disposed on the silicon substrate in the silicon dioxide layer, in which each of the EAM and PD comprises a respective epitaxial structure having an input port and an output port, and in which the polysilicon element abuts the epitaxial structure of the EAM at the input and output ports or the polysilicon element abuts the epitaxial structure of the PD at the input and output ports.

19. The method of claim 12 in which the epitaxy inhibition layer disposed over the silicon dioxide layer comprises a first epitaxy inhibition layer and the first manufacturing stage comprises:
forming a first cavity in the PIC structure using photolithography and chemical etching, the cavity extending through a first epitaxy inhibition layer and the silicon dioxide layer in the PIC structure and into a first rib waveguide formed in the silicon substrate;
using selective area epitaxy for growing a first epitaxial structure in the first cavity in the PIC structure, the first epitaxial structure comprising one of a PD or an EAM;
depositing a first protection layer over a top surface of the PIC structure;
selectively etching the first protection layer to remove portions of the first protection layer except for a remaining portion that is positioned above the first epitaxial structure;
depositing a second epitaxy inhibition layer over the top surface of the PIC structure.

20. The method of claim 19 in which the second manufacturing stage comprises:
subsequent to the deposition of the second epitaxy inhibition layer, forming a second cavity in the PIC structure using photolithography and chemical etching, the cavity extending through the second epitaxy inhibition layer, the first epitaxy inhibition layer, and the silicon dioxide layer and into the second rib waveguide formed in the silicon substrate;
using selective area epitaxy for growing a second epitaxial structure in the second cavity in the PIC structure, the second epitaxial structure being different from the first epitaxial structure and comprising one of a PD or an EAM; and
applying a second protection layer over the top surface of the PIC structure.
